(19) United States
(12) Patent Application Publication
(10) Pub. No.: US 2010/0246920 A1
(43) Pub. Date: Sep. 30, 2010

(54) RECURSIVE SPARSE RECONSTRUCTION

(75) Inventor: Namrata Vaswani, Ames, IA (US)

Correspondence Address: MCKEE, VOORHEES & SEASE, P.L.C., 801 GRAND AVENUE, SUITE 3200, DES MOINES, IA, 50309-2721, US

(73) Assignee: IOWA STATE UNIVERSITY RESEARCH FOUNDATION, INC., Ames, IA (US)

(21) Appl. No.: 12/751,427

(22) Filed: Mar. 31, 2010

Related U.S. Application Data
(60) Provisional application No. 61/165,298, filed on Mar. 31, 2009.

(51) Int. Cl. G06K 9/62; H03M 7/30

(52) U.S. Cl. 382/131; 341/87

(57) ABSTRACT

A method for real-time reconstruction is provided. The method includes receiving a sparse signal sequence one at a time and performing compressed sensing on the sparse signal sequence in a manner which causally estimates a time sequence of spatially sparse signals and generates a real-time reconstructed signal. Recursive algorithms provide for causally reconstructing a time sequence of sparse signals from a greatly reduced number of linear projection measurements.

### CROSS-REFERENCE TO RELATED APPLICATIONS

This application claims priority under 35 U.S.C. §119 to provisional application Ser. No. 61/165,298 filed Mar. 31, 2009, herein incorporated by reference in its entirety.

### GRANT REFERENCE

This invention was made with government support under Grant Nos. ECCS-0725849 and CCF-0917015 granted by NSF. The Government has certain rights in the invention.

### FIELD OF THE INVENTION

The present invention relates to signal processing and applications thereof. More specifically, although not exclusively, the present invention relates to causal reconstruction of time sequences of sparse signals.

### BACKGROUND OF THE INVENTION

Compressed sensing recognizes that a small group of non-adaptive linear projections of a compressibly signal contain sufficient information for reconstruction. Yet despite the benefits of compressed sensings, problems remain. One problem is that most compressed sensing solutions are performed offline and are slow, thus not conducive to real-time applications. Another problem with some approaches is that too many measurements per unit time are required for accurate reconstruction which effectively translates into longer scan time.

Although the present invention has numerous applications, for purposes of providing background, discussion will focus on several specific problems. One such problem is the need to provide real-time capture and reconstruction for Magnetic Resonance Imaging (MRI). Known commercially available systems do not allow for dynamic MRI reconstruction in real-time. Such systems measure a limited number of Fourier coefficients. What is needed is a way to make dynamic MRI reconstruction in real-time. The ability to perform such processing would allow for interventional radiology to be performed.

Another, seemingly unrelated problem is the single-pixel video camera. Although compressive sensing (CS) has been used to provide for imaging with a single-pixel video camera, current systems reconstruct the image off-line, i.e. capture the data first for the entire video first and reconstruct it later. Thus real-time displaying cannot be achieved. What is needed is a method which can be used for real-time video capture and display using the single-pixel camera. Yet another seemingly unrelated problem involves sensor networks. What is needed is real-time estimation of temperature or other random fields using a sensor network.

What is needed to address these and other problems is a way to causally estimate a time sequence of spatially sparse signals.

### BRIEF SUMMARY OF THE INVENTION

Therefore, it is a primary object, feature, or advantage of the present invention to improve over the state of the art.

It is a further object, feature, or advantage of the present invention to causally estimate a time sequence of spatially sparse signals.

A still further object, feature, or advantage of the present invention it to provide for real-time capture and reconstruction for magnetic resonance imaging.

Another object, feature, or advantage of the present invention is to provide a method which facilitates real-time video capture and display using a single-pixel camera.

Yet another object, feature, or advantage of the present invention is to provide a method for use in static as well as dynamic reconstructions.

A further object, feature, or advantage of the present invention is to provide methods which allow for exact reconstruction in cases where compressive sensing does not permit exact reconstruction.

One or more of these and/or other objects, features, and advantages of the present invention will become apparent from the specification and claims that follow. No single embodiment need exhibit all of these objects, features, or advantages of the present invention. The present invention is not to be limited by these objects, features, or advantages.

According to one aspect of the present invention, a method for real-time reconstruction is provided. The method includes receiving a sparse signal sequence one at a time and performing compressed sensing on the sparse signal sequence in a manner which causually estimates a time sequence of spatially sparse signals and generates a real-time reconstructed signal. The compressed sensing may be Kalman filtered compressed sensing, least squares compressed sensing, or a modified-compressed sensing. The method may further include displaying a visual representation of the real-time reconstructed signal on a display. The visual representation may be, for example, a series of MR1 images or a series of CT images. The sequence of sparse signals may be generated by any number of sources, including single pixel cameras, medical imaging scanners, or sensor networks. The step of performing the filtered compressed sensing may include using compressed sensing to estimate signal support at an initial time instant, running a Kalman Filter for a reduced order model until innovation or filtering error increases, and if innovation or filtering error increases then running compressed sensing on the filtering error. Alternatively, the step of performing the compressed sensing may involve computing a Least Squares initial estimate and a Least Squares residual. The step of performing the compressed sensing may involve performing a reconstruction of a signal from the sparse signal sequence by solving a problem both satisfying a data constraint and having a support set containing a smallest number of new additions to a partially known support set.

According to another aspect of the present invention, an apparatus for providing real-time reconstruction of a time-sequence of sparse signals is provided. The apparatus includes a sensor for sensing a sparse signal and a processor for performing compressed sensing on the sparse signal to causually estimate a time sequence of spatially sparse signals and generate a real-time reconstructed signal. The sensor may be associated with a single pixel camera, associated with a sensor network, or associated with medical imaging.

According to another aspect of the present invention, a method for performing Kalman filtered compressed sensing is provided. The method may include receiving a sparse signal sequence one at a time, estimating a support set using compressed sensing for a first sparse signal within the sparse signal sequence, applying a reduced order Kalman filter with the support set to subsequent sparse signals within the sparse signal sequence, and estimating additions to the support set using compressed sensing and updating the support set. The step of estimating additions to the support set may involve applying compressed sensing to Kalman innovations or applying compressed sensing to filtering error. The method may further include displaying a visual representation of sparse signals within the sparse signal sequence on a display.

According to another aspect of the present invention, a method for performing least squares compressed sensing is provided. The method includes receiving a sparse signal sequence one at a time. The method further includes estimating a support set using compressed sensing for a first sparse signal within the sparse signal sequence, applying least squares estimation with the support set to subsequent sparse signals within the sparse signal sequence, and estimating additions to the support set using compressed sensing and updating the support set.

According to another aspect of the present invention, a method for performing modified compressed sensing is provided. The method includes receiving a sparse signal; determining a partially known support set, T. The method further includes performing a reconstruction of a signal from the sparse signal by solving a problem both satisfying a data constraint and having a support set containing a smallest number of new additions to the partially known support set, T. The method may further include outputting the signal or displaying a visual representation of the signal. The step of determining the partially known support set, T, may be performed by using a support set of a prior sparse signal in a time sequence of sparse signals.

### BRIEF DESCRIPTION OF THE DRAWINGS

FIGS. 1A and 1B illustrate MSE plots of KF-CS (labeled CS-KF) with initial nonzero set, T₁, unknown and known cases, compared against regular CS in the first 3 figures and against the Full 256-dim KF in the last figure (its MSE is so large that we cannot plot it in the same scale as the others). The benchmark (MMSE estimate with known T₁, T₅) is the genie-aided KF. The simulated signal's energy at t is

$$E ⌊ {‖ {x}_{t} ‖}_{2}^{2} ⌋ = {S}_{1} {σ}_{init}^{2} + ( {\sum }_{T = 2}^{t} {S}_{T} ) {σ}_{sys}^{2} ) .$$

FIG. 2 illustrates modified-CS for time sequence reconstruction.

FIG. 3A illustrates reconstructing a 32×32 sparsified cardiac image (m=1024) from n=0.19m=195 random Fourier measurements. Support size |T∪Δ|=107 and |T|=64. Modified-CS achieved exact reconstruction, while the CS reconstruction error (square root of normalized MSE) was 13%.

FIG. 3B illustrates reconstruction using n=0.29m random Gaussian measurements. Modified-CS achieved exact reconstruction, while the CS reconstruction error was 34%.

FIG. 4A illustrates exact reconstruction of a sparsified cardiac sequence from only n=0.16m random Fourier measurements (MR imaging). Support size Nₜ≈0.1m. Simple CS (referred to as CS in the figure) has very large (20-25%) error while modified-CS gives exact reconstruction.

FIG. 4B illustrates reconstructing a real cardiac sequence from n=0.19m random Gaussian measurements. We plot the square root of normalized MSE everywhere.

FIG. 5A illustrates top: larynx image sequences and bottom: cardiac sequence.

FIG. 5B provides slow support change plots. Left: additions, Right: removals.

FIG. 6A, 6B illustrate reconstructing the sparsified 32×32 cardiac image sequence.

FIG. 7A, 7B illustrate reconstructing a 32×32 block of the actual (compressible) larynx sequence from random Gaussian measurements.

FIG. 8A, 8B, 8C illustrate reconstructing the 256×256 actual (compressible) vocal tract (larynx) image sequence from simulated MRI measurements.

FIG. 9A illustrates a NMSE comparison (y axis is log scale) for a dynamic MRI reconstruction of a sparsified cardiac sequence.

FIG. 9B illustrates original and reconstructed frames from the dynamic reconstruction of a sparsified cardiac sequence.

FIG. 10 is a block diagram illustrating one example of an apparatus.

### DETAILED DESCRIPTION

We consider the problem of reconstructing time sequences of spatially sparse signals (with unknown and time-varying sparsity patterns) from a limited number of linear “incoherent” measurements, in real-time. The signals are sparse in some transform domain referred to as the sparsity basis. For a single spatial signal, the solution is provided by Compressed Sensing (CS). The question that we address is, for a sequence of sparse signals, can we do better than CS, if (a) the sparsity pattern of the signal's transform coefficients' vector changes slowly over time, and (b) a simple prior model on the temporal dynamics of its current non-zero elements is available. Various examples of the design and analysis of recursive algorithms for causally reconstructing a time sequence of sparse signals from a greatly reduced number of linear projection measurements are provided.

In section 1 we analyze least squares and Kalman filtered compressed sensing. Here, the overall idea is to use CS to estimate the support set of the initial signal's transform vector. At future times, run a reduced order Kalman filter with the currently estimated support and estimate new additions to the support set by applying CS to the Kalman innovations or filtering error (whenever it is “large”). Alternatively, a least squares estimation may replace the Kalman filter.

In section 2, we study the problem of reconstructing a sparse signal from a limited number of its linear projections when a part of its support is known. This may be available from prior knowledge. Alternatively, in a problem of recursively reconstructing time sequences of sparse spatial signals, one may use the support estimate from the previous time instant as the “known” part of the support. The idea of our solution (modified-CD) is to solve a convex relaxation of the following problem: find the signal that satisfies the data constraint and whose support contains the smallest number of new additions to the known support. We obtain sufficient conditions for exact reconstruction using modified-CS. These turn out to be much weaker than those needed for CS, particularly, when the known part of the support is large compared to the unknown part.

In section 3, additional extensions of modified-CS are provided. In section 4, least squares CS-residual) (LS-CS) is introduced. In section 5, applications are discussed.

### 1. ANALYZING LEAST SQUARES AND KALMAN FILTERING COMPRESSED SENSING

### 1.1 Introduction

We consider the problem of reconstructing time sequences of spatially sparse signals (with unknown and time-varying sparsity patterns) from a limited number of linear “incoherent” measurements, in real-time. The signals are sparse in some transform domain referred to as the “sparsity basis” [1]. A common example of such a problem is dynamic MRI or CT to image deforming human organs or to image brain neural activation patterns (in response to stimuli) using fMRI. The ability to perform real-time MRI capture and reconstruction can make interventional MR practical [2]. Human organ images are usually piecewise smooth and thus the wavelet transform is a valid sparsity basis [1, 3]. Due to strong temporal dependencies, the sparsity pattern usually changes slowly over time. MRI captures a small (sub-Nyquist) number of Fourier transform coefficients of the image, which are known to be “incoherent” with respect to the wavelet transform [1, 3]. Other example problems include sequentially estimating optical flow of a single deforming object (sparse in Fourier domain) from a set of randomly spaced optical flow measurements (e.g. those at high intensity variation points [4]), or real-time video reconstruction using the single-pixel camera [5].

The solution to the static version of the above problem is provided by Compressed Sensing (CS) [1, 6, 7]. The noise-free observations case [1] is exact, with high probability (w.h.p.), while the noisy case [7] has a small error w.h.p. But existing solutions for the dynamic problem [5, 8] treat the entire time sequence as a single spatiotemporal signal and perform CS to reconstruct it. This is a batch solution (need to wait to get the entire observation sequence) and has very high complexity. An alternative would be to apply CS at each time separately, which is online and low-complexity, but will require many more measurements to achieve low error. The question that we address is: can we do better than performing CS at each time separately, if (a) the sparsity pattern (support set) of the transform coefficients' vector changes slowly, i.e. every time, none or only a few elements of the support change, and (b) a prior model on the temporal dynamics of its current non-zero elements is available.

Our solution is motivated by reformulating the above problem as causal minimum mean squared error (MMSE) estimation with a slow time-varying set of dominant basis directions (or equivalently the support of the transform vector). If the support is known, the MMSE solution is given by the Kalman filter (KF) [9] for this support. But what happens if the support is unknown and time-varying? The initial support can be estimated using CS [7]. If at a given time, there is an addition to the support set, but we run the KF for the old model, there will be a model mismatch and the innovation (and filtering) error will increase. Whenever it does, the change in support can be estimated by running CS on the innovation or the filtering error, followed by thresholding. A Kalman update step is run using the new support set. If some coefficients become and remain nearly zero (or nearly constant), they can be removed from the support set.

If, for a moment, we assume that CS [7] gives the correct estimate of the support at all times, then the above approach will give the MIVISE estimate of the signal at all times. The reason it is very likely that CS [7] gives the correct estimate is because we use it to fit a very sparse “model change” signal to the filtering error. Also note that a full Kalman filter [9], that does not use the fact that the signal is sparse, is meaningless here, because the number of observations available is smaller than the signal dimension, and thus many elements of the signal transform will be unobservable. Unless all unobservable modes are stable, the error will blow up. Other recent work that also attempts to use prior knowledge with CS, but to reconstruct only a single signal is [10, 11, 12].

### 1.2. The Model and Problem Formulation

Let (zₜ)_{m×1} denote the spatial signal of interest at time t and (yₜ)_{n×1}, with n<m, denote its observation vector at t. The signal, zₜ, is sparse in a given sparsity basis (e.g. wavelet) with orthonormal basis matrix, Φ_{m×m}, i.e. xₜ [symbol] Φ′zₜ is a sparse vector (only Sₜ<<m elements of xₜ are non-zero). Here ′ denotes transpose. The observations are “incoherent” w.r.t. the sparsity basis of the signal, i.e. yₜ=H_{z}_{ₜ}+wₜ=HΦxₜ+wₜ where H_{n×m} is such that the correlation between the columns of A [symbol] HΦ is small enough to ensure that, for any S≦Sₜ any S-column sub-matrix of A is “approximately orthonormal” (its nonzero singular values are between \sqrt{1−δ} to \sqrt{1+δ} for δ<1) [7]. wₜ is i.i.d. Gaussian measurement noise. Thus the measurement model is:)

yₜ=Axₜ+wₜ,A [symbol] HΦ,wₜ˜N(0,σ_{obs}²I) (1.1)

We refer to xₜ as the state at t. Our goal is to get the “best” causal estimate of xₜ (or equivalently of the signal, zₜ=Φxₜ) at each t.

Let Tₜ denote the support set of xₜ, i.e. the set of its nonzero coordinates and let Sₜ=size(T). In other words, Tₜ=[i₁, i₂, . . . isₜ] where iₖ are the non-zero coordinates of xₜ. For any set T, let (v)_{T} denote the size(T) length sub-vector containing the elements of v corresponding to the indices in the set T. For another set, γ, we also use the notation T_{γ} which treats T as a vector and selects the elements of T corresponding to the indices in the set γ. For a matrix A, A_{T} denotes the sub-matrix obtained by extracting the columns of A corresponding to the indices in T. We use the notation (Q)_{T}_{₁}_{T}_{₂} to denote the sub-matrix of Q containing rows and columns corresponding to the entries in T₁ and T₂ respectively. The set operations ∪, ∩, and \ have the usual meanings (note T₁\T₂ denotes elements of T₁ not in T₂). We use ′ to denote transpose. r denotes the complement of T w.r.t. [1:m], i.e. T^{c} [symbol] [1:m]\T. Also ∥v∥ₚ is the lₚ norm of the vector v, i.e. ∥v∥ₚ [symbol] (Σᵢ|vᵢ|^{p})^{1/p}.

Assumption 1. We assume slow changes in sparsity patterns, i.e. the maximum size of the change in the support set at any time is smaller (usually much smaller) than Sₜ at any t, i.e., S_{diff,max} [symbol] maxₜ[size(Tₜ\Tₜ₋₁)+size(Tₜ₋₁\T₁)]<minₜSₜ.

Assumption 2. We also assume that A satisfies δ_{2S}_{ₘₐₓ}+δ_{3S}_{ₘₐₓ}<1 where δ_{S} is the RIP constant defined in equation 1.3 of [7] and Sₘₐₓ [symbol] maxₜSₜ. It should be possible to apply the proposed algorithm even under a slightly weaker assumption that only requires δ2Sₘₐₓ<1 (required to ensure any Sₘₐₓ or less column sub-matrix of A is full rank and hence the state is observable) and δ_{2S}_{_{diff max}}+δ_{3S}_{_{diff min}}<1. This is part of ongoing work.

System Model for xₜ. For the currently non-zero coefficients of xₜ, we assume a spatially i.i.d. Gaussian random walk model, with noise variance σ_{sys}². At the first time instant at which (xₜ)ᵢ becomes non-zero, it is assumed to be generated from a zero mean Gaussian with variance σᵢₙᵢₜ². Thus, we have the model: x₀=0,

(xₜ)ᵢ=(xₜ₋₁)ᵢ+(vₜ)ᵢ,(vₜ)ᵢ˜N(0,σ_{sys}²), if iεTₜ, iεTₜ₋₁

(xₜ)ᵢ=(xₜ₋₁)ᵢ+(vₜ)ᵢ,(vₜ)ᵢ˜N(0,σᵢₙᵢₜ²), if iεTₜ, i∉Tₜ₋₁

(xₜ)=(xₜ₋₁)ᵢ if i∉Tₜ (1.2)

The above model can be compactly written as: x₀=0,

xₜ=xₜ₋₁+vₜ,vₜ˜N(0,Qₜ)

(Qₜ)Tₜ∩T_{t-1,}Tₜ∩Tₜ₋₁=σ_{sys}²I

(Qₜ)Tₜ\T_{t-1,}Tₜ\Tₜ₋₁=σᵢₙᵢₜ²I

(Qₜ)Tₜ^{c},Tₜ^{c}=0 (1.3)

where the set Tₜ is unknown ∀t. If Tₜ were known at each t, i.e. the system model was completely defined, the MMSE estimate of xₜ from y₁, y₂, . . . yₜ would be given by a reduced order KF defined for (xₜ) Tₜ. But, as explained in Sec. 1.1, in most practical problems, Tₜ is in fact unknown and time-varying. Often, it may be possible to get a rough prior estimate of T₁ by thresholding the eigenvalues of the covariance of x₁ (possible to do if multiple realizations of x₁ are available to estimate its covariance). But without multiple i.i.d. realizations of the entire {xₜ}, which are impossible to obtain in most cases, it is not possible to get a-priori estimates of Tₜ for all t. But note that, it is possible to estimate σ_{sys}², σᵢₙₜ² for the model of (3) using just one “training” realization of {xₜ} (which is usually easy to get) by setting the near-zero elements to zero in each xₜ and using the rest to obtain an ML estimate.

Assuming known values of σ_{sys}², σᵢₙᵢₜ², our goal here is to get the best estimates of Tₜ and xₜ at each t using y₁, . . . yₜ. Specifically,

1. At each time, t, get the best estimate of the support set, Tₜ, i.e. get an estimate \hat{T}ₜ with smallest possible [size(\hat{T}ₜ\Tₜ)+size(\hat{T}ₜ\Tₜ)] using y₁, y₂, . . . yₜ.

2. Assuming the estimates of T₁, . . . Tₜ are perfect (have zero error), get the MMSE estimate of xₜ using y₁, y₂, . . . yₜ.

### 1.3. Kalman Filtered Compressed Sensing (KF-CS)

We explain Kalman Filtered Compressed Sensing (KF-CS) below. We misuse notation to also denote the estimated nonzero set by Tₜ.

Running the KF. Assume, for now, that the support set at t=1, T₁, is known. Consider the situation where the first change in the support occurs at a t=tₐ, i.e. for t<tₐ, Tₜ=T₁, and that the change is an addition to the support. This means that for t<tₐ, we need to just run a regular KF, which assumes the following reduced order measurement and system models: yₜ=A_{T}(xₜ)_{T}+wₜ, (xₜ)_{T}=(xₜ₋₁)_{T}+(vₜ)_{T}, with T=T₁. The KF prediction and update steps for this model are [9]: \hat{x}₀=0, P₀=0,

\hat{x}_{t|t-1}=\hat{x}ₜ₋₁

(P_{t|t-1})_{T,T}=(Pₜ₋₁)_{T,T}σ_{sys}²I (1.4)

K_{t,T} [symbol] (P_{t|t-1})_{T,T}A_{T}′Σ_{ie,t,}⁻¹Σ_{ie,t} [symbol] A_{T}(P_{t|t-1})_{T,T}A_{T}′+σ_{obs}²I

(\hat{x}ₜ)_{T}=(\hat{x}t|t-1)_{T}+K_{t,T}└yₜ−A\hat{x}_{t|t-1}┘

(\hat{x}ₜ)_{T}_{^{c}}=(\hat{x}t|t-1)_{T}_{^{c}}=(\hat{x}ₜ₋₁)_{T}_{^{c}}

(Pₜ)_{T,T}=[I−K_{t,T}A_{T}](P_{t|t-1})_{T,T} (1.5)

Detecting If Addition to Support Set Occurred. The Kalman innovation error is \tilde{y}ₜ [symbol] yₜ−A\hat{x}_{t|t-1}. For t<tₐ, \tilde{y}ₜ=└A_{T}(xₜ+\tilde{x}_{t|t-1})_{T}+wₜ┘˜N(0,Σ_{ie,t}) [9]. At t=tₐ, a new set, Δ, gets added to the support of xₜ, i.e. yₜ=A_{T}(xₜ)_{T}+A_{Δ}(xₜ)_{Δ}+wₜ, where the set Δ is unknown. Since the old model is used for the KF prediction, at t=tₐ, \tilde{Y}ₜ will have non-zero mean, A_{Δ}(xₜ)_{Δ}, i.e.

\tilde{y}ₜ=A_{Δ}(xₜ)_{Δ}+\tilde{w}ₜ=A_{T}_{^{c}}(xₜ)_{T}_{^{c}}+ŵₜ, where

\tilde{w}ₜ [symbol] [A_{T}(xₜ−\hat{x}_{t|t-1})_{T}+wₜ]˜N(0,Σ_{ie,t}) 1.6)

where Δ [symbol] T_{c} is the undetected nonzero set at the current time. Thus, the problem of detecting if a new set has been added or not gets transformed into the problem of detecting if the Gaussian distributed j, has non-zero or zero mean. Note that A_{Δ}(xₜ)_{Δ}=A_{Tc}(xₜ)_{T}^{c} and thus the generalized Likelihood Ratio Test (G-LRT) for this problem simplifies to detecting if the weighted innovation error norm, I E N [symbol] \tilde{y}ₜ′Σ_{ie,t}⁻¹\tilde{y}_{t<}^{>} threshold. Alternatively, one can apply G-LRT to the filtering error, \tilde{y}_{t,f} [symbol] yₜ−A\hat{x}_{t′}\tilde{y}_{t,f} can be written:

$$\begin{matrix}{\tilde{y}}_{t , f} = {{A}_{Δ} ( {x}_{t} )}_{Δ} + {{A}_{T} ( {x}_{t} - {\hat{x}}_{t} )}_{T} + {w}_{t} \\ = [ I - {A}_{T} {K}_{t , T} ] {{A}_{Δ} ( {x}_{t} )}_{Δ} + {\tilde{w}}_{t , f} {\tilde{w}}_{t , f} [ I - {A}_{T} K ] {\tilde{w}}_{t}\end{matrix} \\ {\tilde{w}}_{t , f} ∼ N ( 0 , {\sum }_{fe , t} ) , {\sum }_{fe , t} [ I - {A}_{T} {K}_{t , T} ] {\sum }_{ie , t} [ I - {A}_{T} {K}_{t , T} ] \qquad ( 1.7 )$$

The filtering error covariance, Σ_{fe.t}<Σ_{ie,t}. Thus, on average, in \tilde{y}_{t,f,} the noise, \tilde{w}_{t,f} is smaller than that in \tilde{y}ₜ (since the change, (xₜ−xₜ₋₁)_{T}, has been estimated and subtracted out), but the new component, A_{Δ}(xₜ)_{Δ}, is also partially suppressed. The suppression is small because A_{T}K_{t,T}A_{Δ}(xₜ)_{Δ}=A_{T}(P_{t|t-1}⁻¹σ_{obs}²+A_{T}′A_{T})⁻¹A_{T}′A_{Δ}(xₜ)_{Δ} (follows by rewriting K_{t,T} using the matrix inversion lemma) and A_{T}′A_{Δ(x}_{ₜ}_{)Δ} is small (because of restricted orthogonality [7, eq. 1.5]). Assuming the suppression is small enough, using \tilde{y}_{t,f} will result in lower misses for a given false alarm rate. Thus we use G-LRT on \tilde{y}_{t,f}.

Estimating the New Additions (using CS). If the filtering error norm, F E N [symbol] \tilde{y}_{t,f}′Σ_{fe,t}⁻¹\tilde{y}_{t,f,} is “high”, there is a need to estimate the new additions' set, Δ. This can be done by applying the Dantzig selector (DS) [7] to \tilde{y}_{t,f} followed by thresholding the output of the DS (as is also done in the Gauss-Dantzig selector), i.e. we compute

$${\hat{β}}_{t} = arg , {min}_{β} {‖ β ‖}_{1 ,} s . t . ‖ {A}_{{T}^{c}}^{′} ( {\tilde{y}}_{t , f} - {A}_{{T}^{c}} β ) ‖ ∞ \leq {λ}_{m} {σ}_{obs} \\ = {( {T}^{c} )}_{nz ,} where nz \{ i , {\hat{β}}_{t , i}^{2} > {α}_{a} \} , \qquad ( 1.8 )$$

Algorithm 1 Kalman Filtered Compressive Sensing (KF-CS)

Initialization: Set \hat{x}₀ = 0, P₀ = 0, T₀ = empty (if unknown) or equal to the
known/partially known support. For t > 0, do,

| | |
|---|---|
| 1. | Set T ← Tₜ₋₁. |
| 2. | KF prediction and update. Run (4) and (5) using the current T. |
| | Compute the filtering error, \tilde{y}_{t,f} Δ yₜ − A\hat{x}ₜ. |
| 3. | $\begin{matrix}Addition ( using CS ) . Compute F E N {Δ}_{=} {\tilde{y}}_{t , f}^{′} {\sum }_{fe , t}^{- 1} {\tilde{y}}_{t , f , } and check if it is \\ greater than its threshold . If it is ,\end{matrix}$ |
| | (a) Run CS on the filtering error followed by thresholding, i.e. |
| | compute \hat{Δ} using (8) [or use (9)]. |
| | (b) The new estimated support is T_{new} = T ∪ \hat{Δ}. |
| | (c) Set T ← T_{new}. Set (P_{t\|t-1})\hat{Δ}, \hat{Δ} = σᵢₙᵢₜ² I. Run the KF update |
| | given in (5) for the current T. |
| | Performance can be improved by iterating the above four steps until |
| | size (\hat{Δ}) = 0 or F E N less than its threshold. |
| 4. | $\begin{matrix}Deletion . Compute the set {\hat{Δ}}_{D} = \{ i ∈ T : {\sum }_{T = t - k + 1}^{t} {( {\hat{x}}_{T} )}_{i}^{2} < k {α}_{d} \} . The \\ new estimated support set is {T}_{new} = T \backslash {\hat{Δ}}_{D} .\end{matrix}$ |
| | $( a ) Set T ← {T}_{nw} . {Set ( {\hat{x}}_{t} )}_{{Δ}_{D}} = 0 , ( {P}_{t \vert t - 1} ) {\hat{Δ}}_{D , [ 1 : m ]} = 0 , {( {P}_{t \vert t - 1} )}_{[ 1 : m ] ,} {\hat{Δ}}_{D} = 0.$ |
| | Run the KF update give in (5). |
| 5. | Assign Tₜ ← T. Output T_{t,} \hat{x}ₜ and the signal estimate, \hat{z}ₜ = Φ \hat{x}ₜ. |
| | Increment t and go to step 1. |

λₘ [symbol] \sqrt{2 log m} and αₐ is the zeroing threshold for addition. Thus, the new estimated support set is T_{new}=T∪ [symbol] . We initialize the prediction covariance along \hat{Δ} as (P_{t|t-1})_{\hat{Δ}, \hat{Δ}}=σᵢₙᵢₜ²I. Since it typically takes a few time instants before a new addition gets detected, it is useful to set σᵢₙᵢₜ² to a higher value compared to σ_{sys}².

Note that the above ignores the fact that the “noise” in \tilde{y}_{t,f} \tilde{w}_{t,f,}, is colored and that the “signal” to be estimated is partially suppressed (explained earlier). Since the suppression is small, the algorithm still works in practice, but the error bound results for the DS cannot be applied. Alternatively, as we explain in ongoing work [13], one can rewrite \tilde{y}_{t,f}=Aβₜ+wₜ where βₜ [symbol] └(xₜ−\hat{x}ₜ)_{T}, (xₜ)_{T}_{^{c}}┘ is a “sparse-compressible” signal with a “large” nonzero part, (xₜ)_{Δ}, a “small” or “compressible” nonzero part, (xₜ−\hat{x}ₜ)_{T} and the zero part, (xₜ)(T∪Δ)^{c}. Then, DS can be applied to estimate the “large” nonzero part as follows (this will correctly detect elements whose value is above the filtering error level):

$${\hat{β}}_{t} = arg , {min}_{β} {‖ β ‖}_{1 ,} s . t . ‖ {A}^{′} ( {\tilde{y}}_{t , f} - A β ) ‖ ∞ \leq {λ}_{m} {σ}_{obs} \\ \{ i ∈ {T}^{c} \text{:} {\hat{β}}_{t , i}^{2} > {α}_{a} \} \qquad ( 1.9 )$$

As we discuss in [13], the above can be analyzed by adapting Theorem 1.2 and Theorem 1.3 of [7]. If the sparsity pattern changes slowly enough and the filtering error is small enough (slow time varying system), it should be possible to show that performing CS on the filtering error, \tilde{y}_{t,f}, to only detect new additions is more accurate than performing regular CS at each t on yₜ to detect the entire vector xₜ (without using knowledge of the previous support set).

KF Update. We run the KF update given in (1.5) with T=T_{new}. This can be interpreted as a Bayesian version of Gauss-Dantzig [7].

Iterating CS and KF-update. Often, it may happen that not all the elements of the true Δ get estimated in one run of the CS step. To address this, CS and KF update can be iterated until F E N goes below a threshold or until \hat{δ} is empty. But there is also a risk of adding too many wrong coefficients.

Deleting Near-Zero Coefficients. Over time, some coefficients may become and remain zero. Alternatively, some coefficients may wrongly get added in the addition step, due to CS error. In both cases, the coefficients need to be removed from the support set Tₜ. One possible way to do this would be to check if (\hat{x}ₜ)ᵢ²<α_{d} or to average its value over the last few time instants. When a coefficient, i, is removed, we need to modify Tₜ, set (\hat{x}ₜ)ᵢ=0 and set (P_{t|t-1})_{i,[1:m]}=0 and (P_{t|t-1})_{[1:m]}=0. As we explain in [13], to prevent too many deletion errors, deletion should be done only when the KF has stabilized (Tₜ has not changed for long enough).

Deleting Constant Coefficients. If a coefficient, i, becomes constant (this may happen in certain applications), one can keep improving the estimate of its constant value by changing the prediction step for it to (P_{t|t-1})_{i,i}=(Pₜ₋₁)_{i,i}. Either one can keep doing this forever (the error in its estimate will go to zero with t) or one can assume that the estimation error has become negligibly small after a finite time and then remove the coefficient index from T. It is not clear what is the correct thing to do in this case.

Initialization. Initially, the support set, T₁ may be roughly known (estimated by thresholding the eigenvalues of the covariance of x₁, which is computable if its multiple realizations are available) or unknown. We initialize KF-CS by setting \hat{x}₀=0, P₀=0 and T₀=roughly known support or T₀=empty (if support is completely unknown). In the latter case, automatically at t=1, the I E N (or F E N) will be large, and thus CS will run to estimate T₁.

The entire KF-CS algorithm is summarized in Algorithm 1.

KF-CS Error Analysis. In ongoing work [13], we are working on finding sufficient conditions under which KF-CS error will converge to that of the genie-aided KF (KF with known nonzero set at each i). This can be used to show KF-CS error stability. The key idea is to analyze the effect of missed and false additions (or false and missed deletions). The extra error due to a missed element, (xₜ)ᵢ, cannot be larger than a constant times the CS error at the current time (which itself is upper bounded by a small value w.h.p. [7]) plus αₐ (due to thresholding). Also, eventually, when the magnitude of (xₜ)ᵢ becomes large enough (exceeds CS error plus threshold), it will get detected by CS at that time w.h.p. Thus, w.h.p., the detection delay will be finite.

We can prevent too many extra coordinates from getting wrongly estimated by having a rough idea of the maximum sparsity of xₜ and using thresholding to only select that many, or a few more, highest magnitude non-zero elements. The deletion scheme is currently being improved. Note that if some true element gets missed by CS (or gets wrongly deleted) because its value was too small, it will, w.h.p., get detected by CS at a future time. Also, as long as rank(A_{T})>size(T) for the currently estimated T (which may contain some extra coordinates), the estimation error will increase beyond MMSE, but will not blow up. The error analysis reveals that if the number of observations is small, KF-CS has a much smaller error than CS [13].

### 1.4. Simulation Results

We simulated a time sequence of sparse m=256 length signals, xₜ, with maximum sparsity Sₘₐₓ. Three sets of simulations were run with Sₘₐₓ=8, 16 and 25. The A matrix was simulated as in [7] by generating n×m i.i.d. Gaussian entries (with n=72) and normalizing each column of the resulting matrix. Such a matrix has been shown to satisfy the UUP at a level C log m [7]. The observation noise variance, σ_{obs}²=((⅓)\sqrt{S_{max/n}})² (this is taken from [7]). The prior model on xₜ was (1.3) with σᵢₙᵢₜ²=9 and σ_{sys}²=1. T₁ (support set of x₁) was obtained by generating Sₘₐₓ−2 unique indices uniformly randomly from [1:m]. We simulated an increase in the support at t=5, i.e. Tₜ=T₁, ∀t<5, while at t=5, we added two more elements to the support set. Thus, Tₜ=T₅, ∀t≧5 had size Sₘₐₓ. Only addition to the support was simulated.

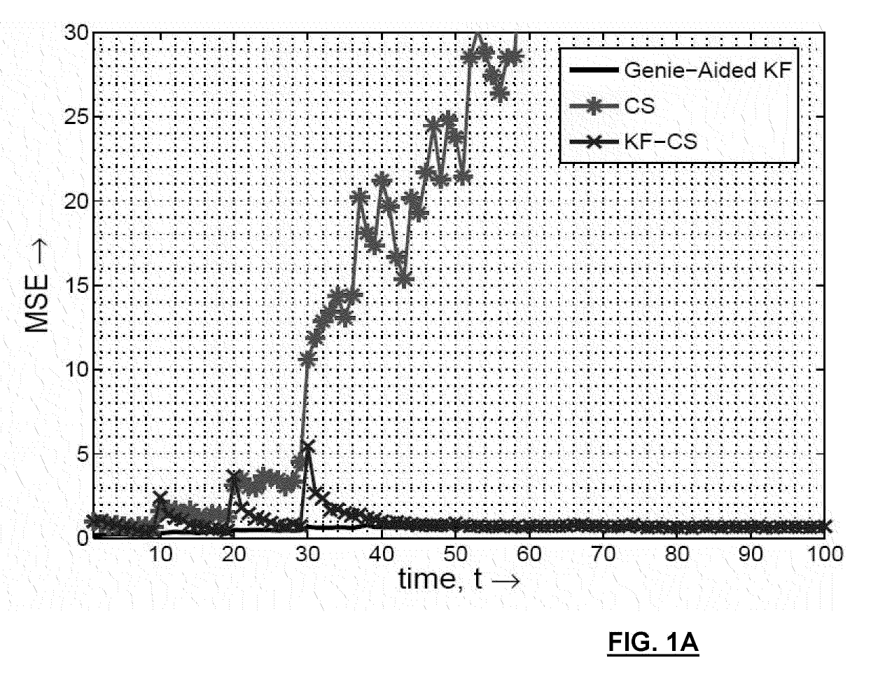

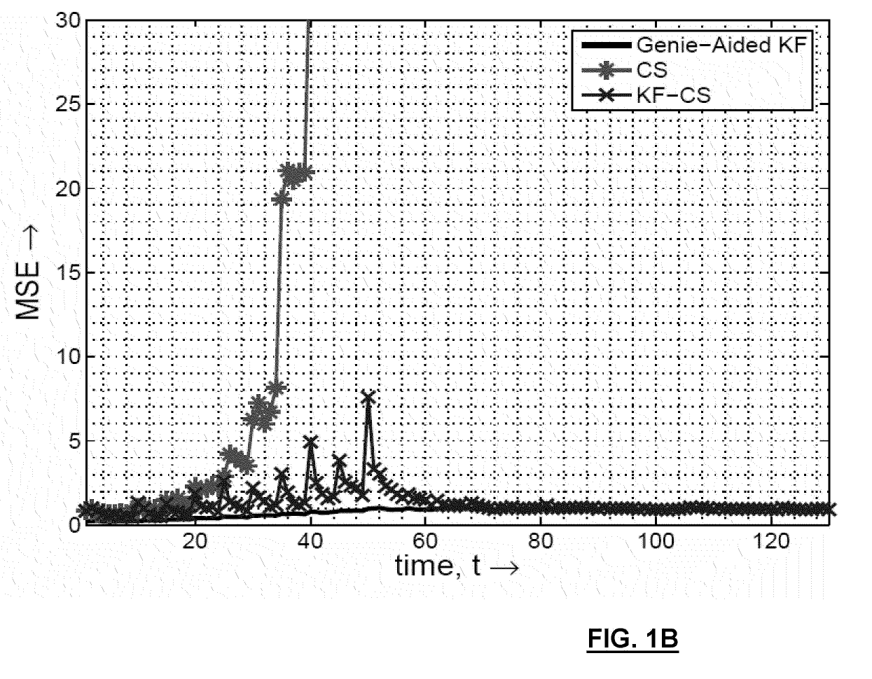

We used the proposed KF-CS algorithm (Algorithm 1), without the deletion step, to compute the causal estimate \hat{x}ₜ of xₜ at each t. The resulting mean squared error (MSE) at each t, [symbol] └∥xₜ−\hat{x}ₜ∥₂²┘, was computed by averaging over 100 Monte Carlo simulations of the above model. The same matrix, A, was used in all the simulations, but we averaged over the joint pdf of x, y, i.e. we generated T₁, T₅, (vₜ) Tₜ, wₜ, t=1, . . . 10 randomly in each simulation. Our simulation results are shown in FIG. 1 (KF-CS is labeled as CS-KF in plots by mistake). Our benchmark was the genie-aided KF, i.e. an Sₘₐₓ-order KF with known T₁ and T₅, which generates the MMSE estimate of xₜ. We simulated two types of KF-CS methods, one with known T₁, but unknown T₅ and the other with unknown T₁ and T₅. Both performed almost equally well for Sₘₐₓ=8, but as Sₘₐₓ was increased much beyond the UUP level of A, the performance of the unknown T₁ case degraded more (the CS assumption did not hold). We also show comparison with regular CS at each t, which does not use the fact that Tₜ changes slowly (and does not assume known T₁ either). This had much higher MSE than KF-CS. The MSE become worse for larger Sₘₐₓ. We also implemented the full KF for the 256-dim state vector. This used (1.3) with Qₜ=σ_{sys}²I_{256×256}, i.e., it assumed no knowledge of the sparsity. Since we had only a 72-length observation vector, the full system is not observable. Since all non-zero modes are unstable, its error blows up. Thus, the present invention provides for extending the CS idea to causally estimate a time sequence of spatially sparse signals.

### 2. MODIFIED-CS: MODIFYING COMPRESSIVE SENSING FOR PROBLEMS WITH PARTIALLY KNOWN SUPPORT

We study the problem of reconstructing a sparse signal from a limited number of its linear projections when a part of its support is known. This may be available from prior knowledge. Alternatively, in a problem of recursively reconstructing time sequences of sparse spatial signals, one may use the support estimate from the previous time instant as the “known” part of the support. The idea of our solution (modified-CS) is to solve a convex relaxation of the following problem: find the signal that satisfies the data constraint and whose support contains the smallest number of new additions to the known support. We obtain sufficient conditions for exact reconstruction using modified-CS. These turn out to be much weaker than those needed for CS, particularly when the known part of the support is large compared to the unknown part.

### 2.1 Introduction

Consider the problem of recursively and causally reconstructing a time sequence of sparse spatial signals (or images) from a sequence of observations, when the current observation vector contains a limited (less-than-Nyquist) number of linear projections of the current signal. The observation vector is assumed to be incoherent with respect to the sparsity basis of the signal/image [1], [14]. Important applications include real-time (causal and recursive) dynamic MRI reconstruction [8], [15], real-time single-pixel video imaging [5] or real-time time varying spatial field estimation using sensor networks [16].

Since the introduction of compressive sensing (CS) in recent work [1], [6] the static version of the above problem has been thoroughly studied. But, with the exception of [17], [18], most existing solutions for the time series problem are noncausal or batch solutions with very high complexity since they jointly reconstruct the entire video by first collecting all the observations. The alternative solution—separately doing CS at each time (simple CS)—is causal and low complexity, but requires many more measurements for accurate reconstruction.

In recent work [13], we studied the causal reconstruction problem from noisy measurements and proposed a solution called Kalman filtered CS and its non-Bayesian version, least squares CS (LS-CS). Our solutions used the empirically observed fact that the sparsity pattern (support set of the signal) changes slowly over time. The key idea of LS-CS was to replace CS on the observation by CS on the LS observation residual computed using the previous estimate of the support. Kalman filtered CS replaced the LS residual by the Kalman filter residual. The reason LS-CS, or Kalman filtered CS, significantly outperformed simple CS was that the signal minus its LS estimate (computed using the previous support estimate) contains much fewer significantly nonzero elements than the signal itself. But note that its exact sparsity size (total number of nonzero coefficients) is larger/equal to that of the signal. Since the number of measurements required for exact reconstruction is governed by the exact sparsity size, one thing we were not able to achieve was exact reconstruction using fewer (noiseless) measurements than those needed by CS.

Exact reconstruction using fewer measurements is the focus of the current work. The idea of our solution (modified-CS) is to modify CS for problems where part of the support is known (in the time sequence case, it is the estimated support from the previous time instant). Denote the known part of the support by T Modified-CS solves an relaxation of the following problem: find the signal that satisfies the data constraint and whose support contains the smallest number of new additions to T (or in other words the support set difference from T is smallest). We derive sufficient conditions for exact reconstruction using modified-CS. These turn out to be much weaker than the sufficient conditions required for simple CS. Experimental results showing greatly improved performance of modified-CS over simple CS are also shown.

Notice that the same idea also applies to a static reconstruction problem where we know a part of the support from prior knowledge. For example, consider MR image reconstruction using the wavelet basis as the sparsifying basis. If it is known that an image has no (or very little) black background, all (or most) elements of the lowest subband of its wavelet coefficients will be nonzero. In this case, the set Tis the set of indices of the lowest subband coefficients.

### A. Problem Definition

We measure an n-length vector y where

y=Ax (2.1)

We need to estimate x which is a sparse m-length vector with m>n. The support of x, denoted N, can be split as N=T∪ [symbol] where T is the “known” part of the support, Δ_{d} is the error in the known part and Δ is the unknown part.

In a static problem, the support T is available from prior knowledge, e.g. it may be the set of the lowest subband wavelet coefficients. Typically there is a small black background in an image, so that only most (not all) lowest subband wavelet coefficients will be nonzero. The indices of the lowest subband coefficients which are zero form Δ_{d}. For the time series problem, y≡yₜ and x≡xₜ with support, N=T∪ [symbol] . Here T:=Nₜ₋₁ is the support estimate from t−1. Also, [symbol] :=T\Nₜ is the set of indices of elements that were nonzero at t−1, but are now zero while [symbol] :=Nₜ\T is the newly added coefficients at time t. Both Δ, Δ_{d} are typically much smaller than |T|. This follows from the empirical observation that sparsity patterns change slowly [13], [15].

In our proposed solution, we compute \hat{x} by assuming that the support of x contains T. When n is large enough for exact reconstruction (i.e. the conditions of Theorem 1 hold), \hat{x}=x and so \hat{x}can be used to compute N (and Δ_{d} if needed).

We assume that the measurement matrix, A, is “approximately orthonormal” for sub-matrices containing S=(|T|+2| [symbol] |) or less columns, i.e. it satisfies the S-RIP [14].

Notation: We use for transpose. The notation ∥c∥ₖ denotes the lₖ norm of the vector c. For a matrix, ∥M∥ denotes its spectral norm (induced l₂norm). We use the notation A_{T} to denote the sub-matrix containing the columns of A with indices belonging to T. For a vector, the notation (β)_{T} forms a sub-vector that contains elements with indices in T.

The S-restricted isometry constant [14], δ_{S}, for a matrix, A, is defined as the smallest real number satisfying

(1−δ_{S})∥c∥₂²≦∥A_{T}c∥₂²≦(1+δ_{S})∥c∥₂² (2.2)

for all subsets T⊂[1:m] of cardinality |T|≦S and all real vectors c of length |T|. S-RIP means that δS<1. A related quantity, the restricted orthogonality constant [14], θ_{S,S′}, is defined as the smallest real number that satisfies

|c₁′A_{T}_{ₜ}∵c₂|≦θ_{S,S′}∥c₁∥₂∥c₂∥₂ (2.3)

for all disjoint sets T₁, T₂⊂[1:m] with |T₁|≦S and |T₂|≦S′ and with S+S′≦m, and for all vectors c₁, c₂ of length |T₁|, |T₂| respectively. By setting c₁≡A_{T}_{₁}′A_{T}_{₂}c₂ in (2.3), it is easy to see that ∥A_{T}_{₁}′A_{T}_{₂}∥≦θ_{S,S′}.

### 2.2 Modified Compressive Sensing (MOD-CS)

Our goal is to find the sparsest possible signal estimate whose support contains T and which satisfies the data constraint (1), i.e. we would like to find a \hat{x} which solves

$${min}_{β} {‖ {( β )}_{{T}^{c}} ‖}_{0} subject to y = A β \qquad ( 2.4 )$$

where T^{c}:=[1:m]\T denotes the complement of T

As is well known, minimizing the l₀ norm has combinatorial complexity. We propose to use the same trick that resulted in compressive sensing. We replace the l₀ norm by the l₁ norm, which is the closest norm to l₀ that makes the optimization problem convex, i.e. we solve

$${min}_{β} {‖ {( β )}_{{T}^{c}} ‖}_{1} subject to y = A β \qquad ( 2.5 )$$

### A. Recursive Reconstruction of Signal Sequences

Consider the recursive reconstruction problem where y≡yₜ and x≡xₜ with support N≡Nₜ. The known part of the support, T=\hat{N}ₜ₋₁. In this case, at each time, t, we solve (2.5) and denote its output by \hat{x}_{t,modCS}. The support at t, \hat{N}ₜ is computed by thresholding \hat{x}_{t,modCS}, i.e.

\hat{N}ₜ={iε[1:m]:(\hat{x}_{t,modCS})ᵢ²>α} (2.6)

where α is a small threshold (ideally zero). With this we automatically estimate [symbol] =\hat{N}ₜ\T and [symbol] _{d}=T\\hat{N}ₜ.

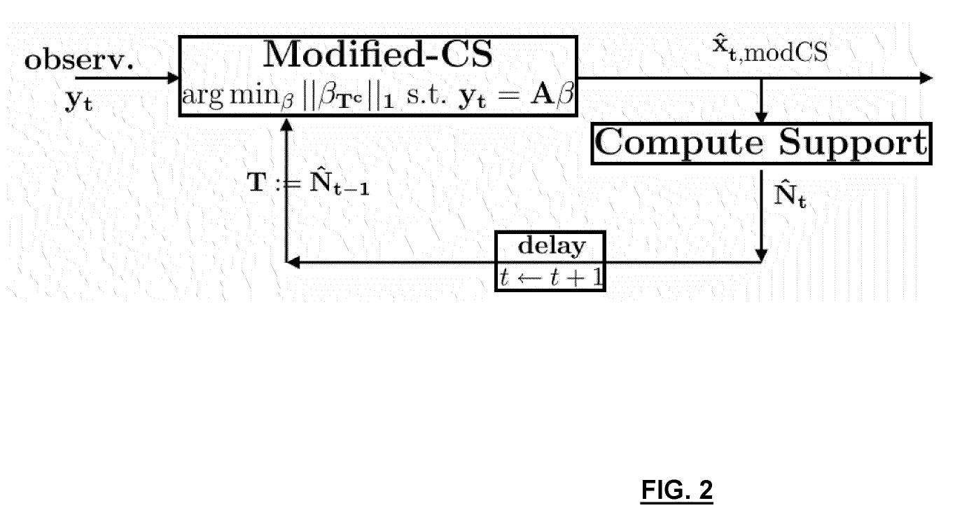

A block diagram of our proposed approach is given in FIG. 2. Note that at t=1, we perform CS and use enough observations for CS to give exact reconstruction.

### 2.3 Exact Reconstruction Result

We first study the l₀ version and then the actual l₁ version.

A. Exact Reconstruction: l₀ version of modified-CS

Consider the l₀ problem, (2.4). Using a rank argument similar to [14, Lemma 1.2] we can show the following

Proposition 1: Given a sparse vector, x, whose support, N=T∪Δ\Δ_{d}, where Δ and T are disjoint and [symbol] _{d} [symbol] T. Consider reconstructing it from y:=Ax by solving (2.4). The true signal, x, is its unique minimizer if δ_{|T|°2|Δ|}<1. Compare this with [14, Lemma 1.2]. Since the l₀ version of CS does not use the knowledge of T, it requires δ_{2|T|+2|Δ|}<1 which is much stronger.

### B. Exact Reconstruction: Modified-CS

We do not solve (2.4) but its l₁ relaxation, (2.5). Just like in CS, the sufficient conditions for this to give exact reconstruction will be slightly stronger. We show the following.

Theorem 1 (Exact Reconstruction): Given a sparse vector, x, whose support, N=T ∪Δ\Δ_{d}, where Δ and T are disjoint and Δ_{d} [symbol] T. Consider reconstructing it from y:=Ax by solving (2.5). x is its unique minimizer if δ_{|T|+|Δ|} and if a(2| [symbol] ,|T|)+a(| [symbol] , [symbol] ,|T|)<1, where

$$a ( S , {S}^{′} , \vert T \vert ) := \frac{{θ}_{{S}^{′} , S} + \frac{{θ}_{{S}^{′} , \vert T \vert} {θ}_{S , \vert T \vert}}{1 - {δ}_{\vert T \vert}}}{1 - {δ}_{S} - \frac{{θ}_{S , \vert T \vert}^{2}}{1 - {δ}_{\vert T \vert}}} \qquad ( 2.7 )$$

To understand the above condition better and relate it to the corresponding CS result [14, Theorem 1.3], let us simplify it a(2| [symbol] , | [symbol] |, |T|)+a(| [symbol] , | [symbol] |, |T|)≦

$$\frac{{θ}_{\vert Δ \vert , 2 \vert Δ \vert} + {θ}_{\vert Δ \vert , \vert Δ \vert} + \frac{{θ}_{2 \vert Δ \vert , \vert T \vert}^{2} + {θ}_{\vert Δ \vert , \vert T \vert}^{2}}{1 - {δ}_{\vert T \vert}}}{1 - {δ}_{2 \vert Δ \vert} - \frac{{θ}_{2 \vert Δ \vert , \vert T \vert}^{2}}{1 - {δ}_{\vert T \vert}}}$$

A sufficient condition for this is

$${θ}_{\vert Δ \vert , 2 \vert Δ \vert} + {θ}_{\vert Δ \vert , \vert Δ \vert} + \frac{2 {θ}_{2 \vert Δ \vert , \vert T \vert}^{2} + {θ}_{\vert Δ \vert , \vert T \vert}^{2}}{1 - {δ}_{\vert T \vert}} + {δ}_{2 \vert Δ \vert} < 1.$$

Further, a sufficient condition for this is θ_{|Δ|,|Δ|}+δ_{2|Δ|+θ}_{|Δ|,2|Δ|+δ}_{|T|}+θ_{|Δ|,|T|}²+2θ_{2|Δ|,|T|}²<1. To get a condition only in terms of δ_{S}'s, use the fact that θ_{S,S′}≦δ_{S+S′}. A sufficient condition is 2δ_{2|Δ|}+δ_{3|Δ|}+δ_{|T|}+δ_{|T|+|Δ|}²+2δ_{|T|+2|Δ|}²<1. Further, notice that if | [symbol] |≦|T| and if δ_{|T|+2|Δ|}<⅕, then 2δ_{2|Δ|}+δ_{3|Δ|}+δ_{|T|}+δ_{|T|+|Δ|}²+2δ_{|T|+2|Δ|}²<4δ_{|T|+2|Δ|}(3δ_{|T|+2|Δ|})≦(4+3/5)δ_{|T|+2|Δ|}<23/25<1.

Corollary 1 (Exact Reconstruction): Given a sparse vector, x, whose support, N=T∪Δ\ [symbol] _{d}, where [symbol] and T are disjoint and [symbol] _{d} [symbol] T. Consider reconstructing it from y:=Ax by solving (2.5). x is its unique minimizer if δ_{|T|+|Δ|}<1 and θ_{|Δ|,|Δ|}+δ_{2|Δ|}+θ_{|Δ|,2|Δ|}+δ_{|T|}+θ_{|Δ|,|T|}²+2θ_{2|Δ|,|T|}²<1. This holds if 2δ_{2|Δ|}+δ_{3|Δ|}+δ_{|r|}+δ_{|T|+|Δ|}²+2δ_{|T|+2|Δ|}<1. This, in turn, holds if |Δ|≦|T| and δ_{|T|°2|Δ|}<⅕.

Compare the above with the requirement for CS: 2δ_{2(|T|+|Δ|)}+δ_{3(|T|+|Δ|)}<1 which holds if δ_{3(|T|+|Δ|)}<⅓. It is clear that if |Δ| is small compared to |T|, δ_{|T|+2|Δ|}<⅕ is a much weaker requirement.

### 2.4 Simulation Results

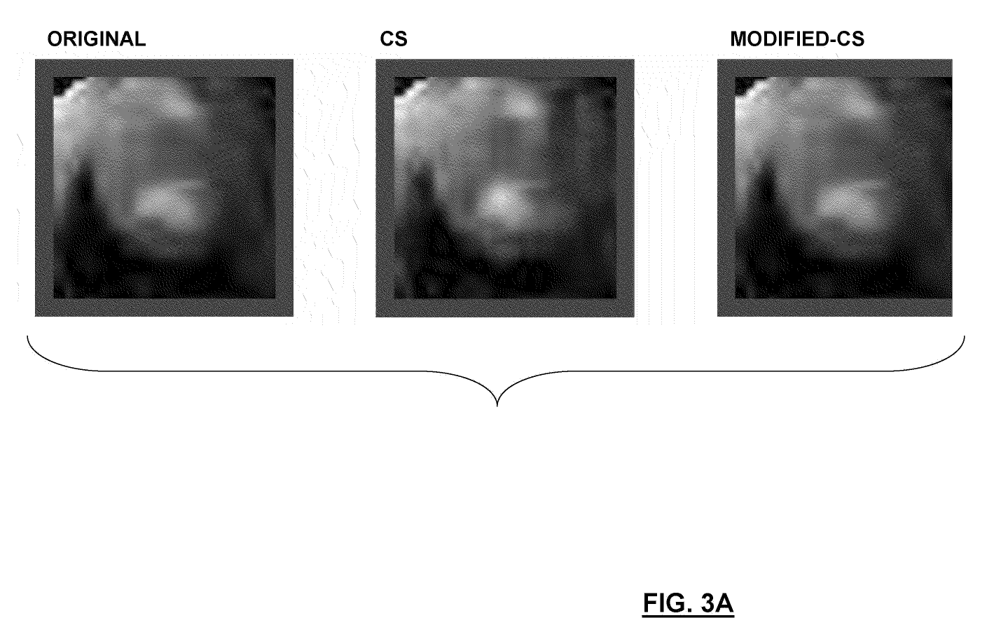

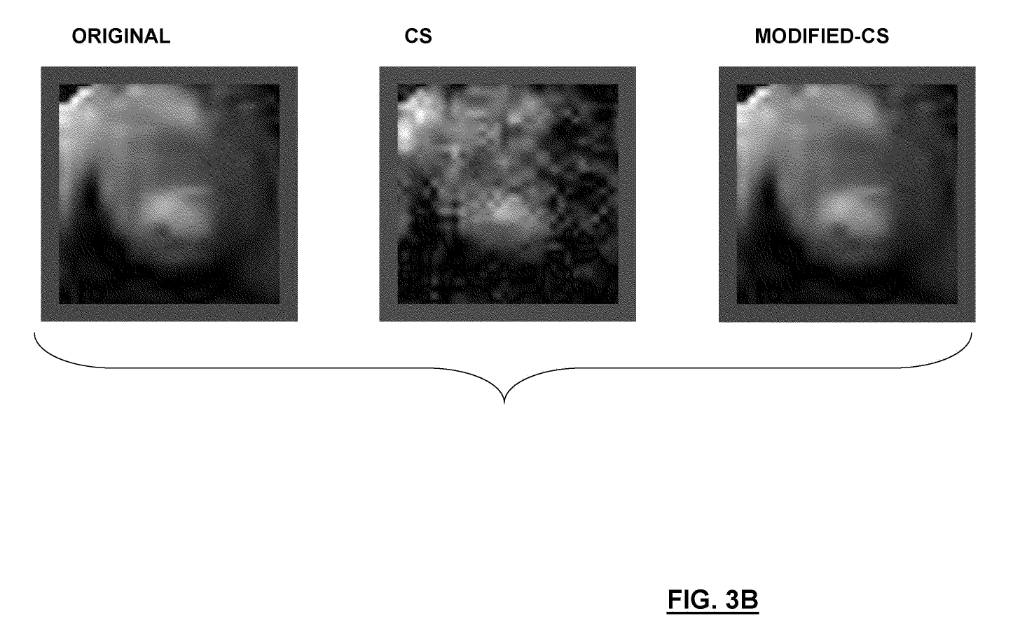

We first evaluated the static problem. The image used was a sparsified 32×32 block (m=1024) of a cardiac image. This was obtained by taking a discrete wavelet transform (DWT) of the original image block, retaining the largest 107 coefficients (corresponds to 99% of image energy) while setting the rest to zero and taking the inverse DWT. A 2-level DWT served as the sparsifying basis. We used its lowest subband as the known part of the support, T. Thus, |T|=64. Support size |N|=107. We show reconstruction from only n=0.19m=195 random Fourier measurements in FIG. 3A. Modified-CS achieved exact reconstruction, while CS reconstruction error (square root of normalized MSE) was 13%. Notice that 195<2|N|=214, which is the minimum n necessary for exact reconstruction using CS for a |N|-sparse vector. Comparison for random-Gaussian measurements is shown in FIG. 3B.

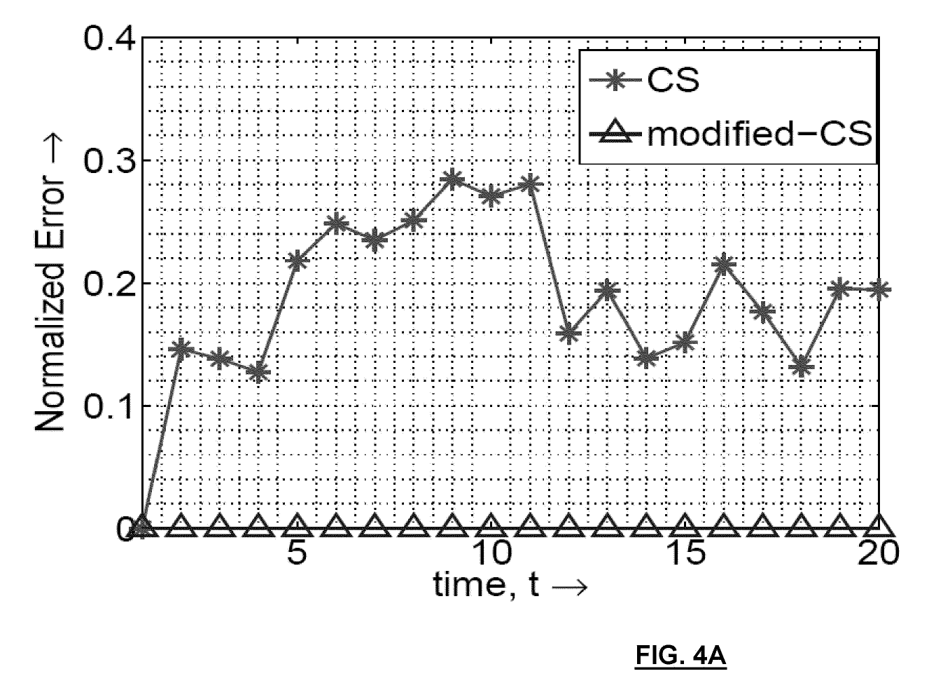

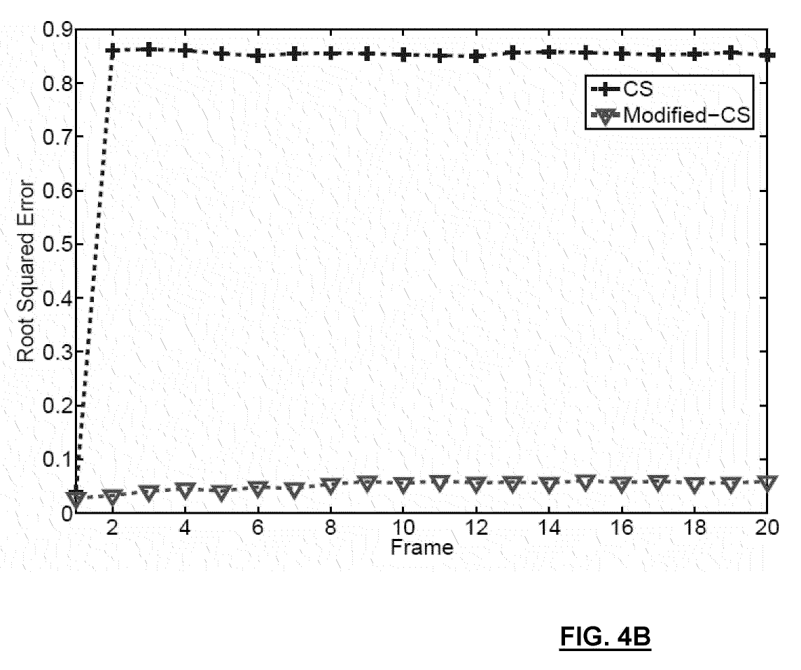

Next, we evaluated the time sequence problem using a sparsified cardiac image sequence created the same way as above. At t=1, we did simple CS and used n=0.5 m=256 random Fourier measurements. For t>1 we did modified-CS and used only n=0.16 m=164 measurements. The size of the change in the support from t−1 to t, | [symbol] |≈0.01 m=10 or less. The support size, |Nₜ|=0.1m=103. We show the reconstruction results in FIG. 4A. Simple CS (referred to as CS in the figure) has very large (20-25%) error while modified-CS gives exact reconstruction.

Finally, we evaluated modified-CS for a real cardiac sequence (not sparsified). In this case, the wavelet transform is only compressible. The comparison is given in FIG. 4B.

### 2.5 Conclusions

We studied the problem of reconstructing a sparse signal from a limited number of its linear projections when a part of its support is known. This may be available from prior knowledge. Alternatively, in a problem of recursively reconstructing time sequences of sparse spatial signals, one may use the support estimate from the previous time instant as the “known” part of the support. We derived sufficient conditions for exact reconstruction using our proposed solution—modified-CS—and discussed why these are weaker than the sufficient conditions required by simple CS. Experiments showing greatly improved performance of modified-CS over simple CS are also given.

The present invention contemplates various options, variations and alternatives, including: (a) bounding the reconstruction error of modified-CS for compressible signals, (b) combining modified-CS with Least Squares CS [13] for the noisy measurements case, and (c) developing Bayesian extensions which also use knowledge of the previously reconstructed signal values and analyzing their performance. Whenever exact reconstruction does not occur, an important question to answer is when will the algorithm be stable over time, i.e. under what conditions will the reconstruction error remain bounded. This automatically holds for modified-CS for noiseless measurements if the assumption of Theorem 1 holds at all times. It has been shown to hold with high probability for LS-CS and KFCS for noisy measurements in [13] under strong assumptions. Thus, the present invention further contemplates modified-CS for noisy measurements under weaker assumptions.

### 3. Extensions of Modified-CS

We now discuss some extensions of modified-CS, which are most useful when exact reconstruction does not occur either m is too small for exact reconstruction or the signal is compressible. Before going further we define the b %-support.

Definition I (b %-energy support or b %-support): For sparse signals, clearly the support is N :={iε[1,n]: xᵢ²>0}. For compressible signals, we misuse notation slightly and let N be the b %-support, i.e. N :={iε[1,n]: xᵢ²>ζ}, where ζ is the largest real number for which N contains at least b % of the signal energy, e.g. b=99.

### A. Dynamic Modified-CS: Modified-CS for Recursive Reconstruction of Signal Sequences

The most important application of modified-CS is for recursive reconstruction of time sequences of sparse or compressible signals. To apply it to time sequences, at each time t, we solve (2.4) with T=\hat{N}ₜ₋₁ where \hat{N}ₜ₋₁ is the support estimate from t−1 and is computed using \hat{N} :={iε[1,n]:(\hat{x})ᵢ²>α}. At t=0 we can either initialize with CS, i.e. set T to be the empty set, or with modified-CS with T being the support available from prior knowledge, e.g. for wavelet sparse images, T could be the set of indices of the approximation coefficients. The prior knowledge is usually not very accurate and thus at t=0 one will usually need more measurements i.e. one will need to use y₀=A₀_{^{x}}₀ where A₀ is an m₀×n, measurement matrix with m₀>m. The full algorithm is summarized later herein.

Setting the support estimation threshold, α. If m is large enough for exact reconstruction, α can be zero. In case of very accurate reconstruction, if we set α to be slightly smaller than the magnitude of the smallest element of the support (if that is roughly known), it will ensure zero misses and fewest false additions. As m is reduced further (error increases), α should be increased further to prevent too many false additions.

For compressible signals, one should do the above but with support replaced by the b %-support, i.e. a should be equal to/slightly smaller than the magnitude of the smallest element of the b %-support. Choose b so that, with the given m, the elements of the b %-support are accurately reconstructed.

Alternatively, one can use other approaches. First, only detect additions to the support using a small threshold (or keep adding largest elements into T as long as A_{T} remains well-conditioned), then compute an LS estimate on that support and then use this LS estimate to perform support deletion using a larger threshold, α, selected as above. If there are few misses in the support addition step, the LS estimate will have lower error than the output of modified-CS, thus making deletion accurate even with a larger threshold.

### B. RegModCS: Regularized Modified-CS

So far we only used prior knowledge about the support to reduce the m required for exact reconstruction or to reduce

Algorithm for Dynamic Modified-CS

At t = 0, compute \hat{x}₀ as the solution of min_{β}∥(β)_{T}_{^{c}}∥₁ , s.t. y₀ = A₀β ,
where T is either empty or is available from prior knowledge. Compute
\hat{N}₀ = {i ∈[1,n]: (\hat{x}₀)ᵢ² > α}. For t > 0, do

1) Modified-CS Let T = \hat{N}ₜ₋₁. Compute \hat{x}ₜ as the solution of

min_{β}∥(β)_{T}_{^{c}}∥₁ , s.t. yₜ = Aβ.

2) Estimate the Support. \hat{N}ₜ = {i ∈[1,n]: (\hat{x}ₜ)ᵢ² > α}.
3) Output the reconstruction \hat{x}ₜ.

Feedback \hat{N}ₜ, increment t, and go to step 1.

the error in cases where exact reconstruction is not possible. If we also know something about how the signal along T was generated, e.g. we know that the elements of X_{T} were generated from some distribution with mean μ_{T}, we can use this knowledge to reduce the reconstruction error by solving

$${min}_{β} {‖ {( β )}_{{T}^{c}} ‖}_{1 + γ} {‖ {( β )}_{T - μ T} ‖}_{2}^{2} s . t . y = A β \qquad ( 3.1 )$$

We call the above Regularized Modified-CS or RegModCS. Denote its output by \hat{x}_{reg}.

We ran a Monte Carlo simulation to compare Modified-CS with RegModCS for sparse signals. We fixed n=256, s=26≈O.ln, u=e=0.08s. We used m=0.16n, 0.12n, 0.11n in three sets of simulations done in a fashion similar to that of Sec. IV-B, but with the following change. In each run of a simulation, we generated each element of μ_{N\Δ} to be i.i.d.±1 with probability (w.p.) ½ and each element of μ_{Δ} and of μ_{Δ}_{ₑ} to be i.i.d. ±0.25 w.p. ½. We generated x_{N}˜N(μ_{N},0.01I) and we set x_{N}_{^{e}}=0. We set y :=Aₓ, We tested RegModCS with various values of γ (γ=0 corresponds to modifiedCS). We used t0t=50. The results are tabulated in the below table.

COMPARING PROBABILITY OF EXACT RECONSTRUCTION
(PROB) AND RECONSTRUCTION ERROR (ERROR) OF
REGMODCS WITH DIFFERENT γ's. γ = 0
CORRESPONDS TO MODIFIED-CS.
(a) m = 0.16 n

| | γ | | | | | |
|---|---|---|---|---|---|---|
| | 0 (modCS) | 0.001 | 0.05 | 0.1 | 0.5 | 1 |
| prob | 0.76 | 0.76 | 0.74 | 0.74 | 0.70 | 0.34 |
| error | 0.0484 | 0.0469 | 0.0421 | 0.0350 | 0.0273 | 0.0286 |

(b) m = 0.12 n

γ

| | 0 (modCS) | 1 |
|---|---|---|
| prob | 0.04 | 0 |
| error | 0.2027 | 0.0791 |

(c) m = 0.11 n

γ

| | 0 (modCS) | 1 |
|---|---|---|
| prob | 0 | 0 |
| error | 0.3783 | 0.0965 |

We computed the exact reconstruction probability by counting the number of times \hat{x}_{reg} equals x and normalizing. As can be seen, RegModCS does not improve the exact reconstruction probability, in fact it can reduce it. This is primarily because the elements of (\hat{x}_{reg})_{Δ}_{ₑ} are often nonzero, though small. But, it significantly reduces the reconstruction error, particularly when m is small.
C. Setting γ, using an MAP interpretation of RegModCS

One way to select γ is to interpret the solution of (3.1) as a maximum a posteriori (MAP) estimate under the following prior model and under the observation model of (2.1). Given the prior support and signal estimates, T and μ_{T}, assume that x_{T} and x_{T}_{_{c}} are mutually independent and

$$\begin{matrix}p ( {x}_{T} \vert T , {μ}_{T} ) = N ( {x}_{T} ; {μ}_{T} , {σ}_{p}^{2} I ) , p ( {x}_{{T}^{c}} \vert T , {μ}_{T} ) \\ = {( \frac{1}{2 {b}_{p}} )}^{\vert {T}_{c} \vert} {e}^{- \frac{{‖ {x}_{{T}^{c}} ‖}_{1}}{{b}_{p}} ,}\end{matrix} \qquad ( 3.2 )$$

i.e. all elements of .r are mutually independent; each element of T^{c} is zero mean Laplace distributed with parameter bₚ; and the i^{th} element of T is Gaussian with mean μᵢ and variance σₚ². Under the above model, if γ=bₚ/2σₚ² a in (30), then, clearly, its solution, \hat{x}_{reg} will be an MAP solution.

Given i.i.d. training data, the maximum likelihood estimate (MLE) of bₚ, σₚ² can be easily computed in closed form [23].

### D. Dynamic Regularized Modified-CS (RegModCS)

To apply RegModCS to time sequences, we solve (3.1) with T=\hat{N}ₜ₌₁, and μ_{T}=(\hat{x}ₜ₋₁)_{T}. Thus, we use the Algorithm for Dynamic Modified-CS with step I replaced by

$${min}_{β} {‖ {( β )}_{{\hat{N}}_{t - 1}^{c}} ‖}_{1 + γ} {‖ {( β )}_{{\hat{N}}_{t - 1}} - {( {\hat{x}}_{t - 1} )}_{{\hat{N}}_{t - 1}} ‖}_{2}^{2} s . t . {y}_{t} = A β \qquad ( 3.3 )$$

In the last step, we feed back \hat{x}ₜ and \hat{N}ₜ.

To summarize the conditions under which the solution of (3.3) becomes a causal MAP estimate, if we set γ=bₚ/2σₚ² where bₚ, σₚ² are the parameters of the signal model given there, and if we assume that the previous signal is perfectly estimated from y₀, . . . yₜ₋₁ with the estimate being zero outside \hat{N}ₜ₋₁ and equal to (\hat{x}ₜ₋₁)_{\hat{N}}_{ₜ₋₁} on it, then the solution of (3.3) will be the causal MAP solution under that model.

In practice, the model parameters are usually not known. But, if we have a training time sequence of signals, we can compute their MLEs.

3.1 Reconstructing Sparsified/True Images from Simulated Measurements

We simulated two applications: CS-based image/video compression (or single-pixel camera imaging) and static/dynamic MRI. The measurement matrix was A=HΦ where Φ is the sparsity basis of the image and H models the measurement acquisition. All operations are explained by rewriting the image as a 1D vector. We used Φ=W′ where W is an orthonormal matrix corresponding to a 2D-DWT for a 2-level Daubechies-4 wavelet. For video compression (or single-pixel imaging), H is a random Gaussian matrix denoted Gᵣ, (i.i.d. zero mean Gaussian m×n matrix with columns normalized to unit l₂ norm). For MRI, H is a partial Fourier matrix, i.e. H=MF where M is an m×n mask which contains a single 1 at different randomly selected locations in each row and all other entries are zero and F is the matrix corresponding to the 2D discrete Fourier transform (DFT).

N-RMSE, defined here as ∥xₜ−\hat{x}ₜ∥₂/∥xₜ∥₂, is used to compare the reconstruction performance. We first used the sparsified and then the true image and then did the same for image sequences. In all cases, the image was sparsified by computing its 2D-DWT, retaining the coefficients from the 99%-energy support while setting others to zero and taking the inverse DWT. We used the 2-level Daubechies-4 2D-DWT as the sparsifying basis. We compare modified-CS and RegModCS with simple CS, CS-diff [24] and LS-CS (described later herein).

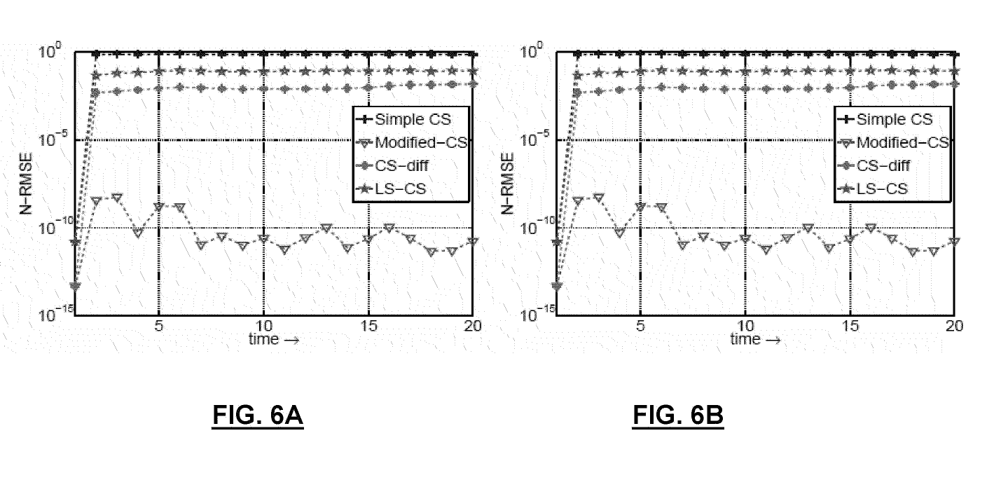

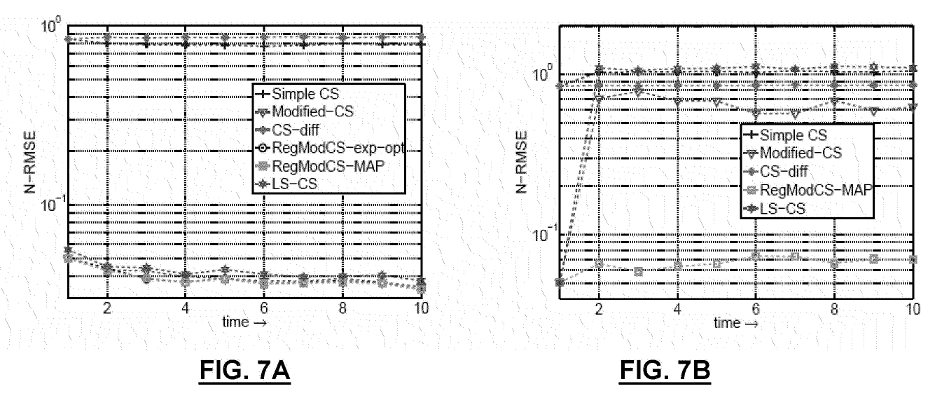

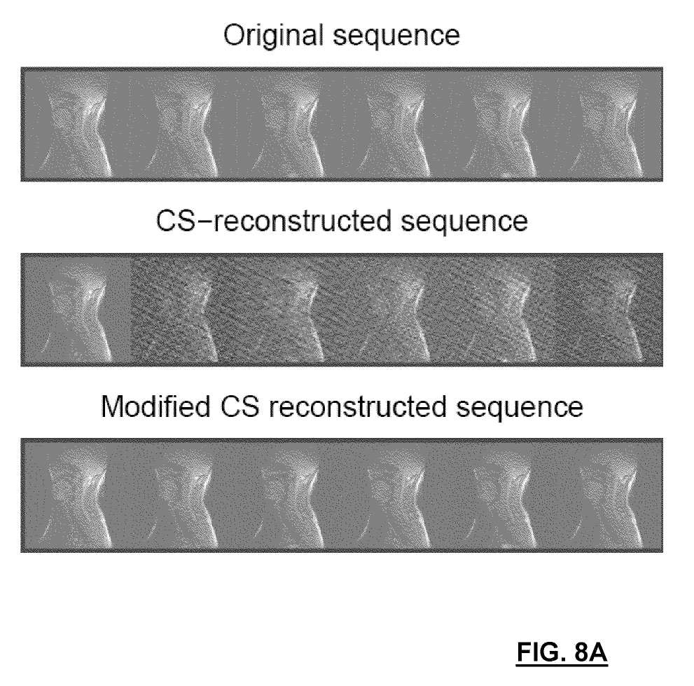

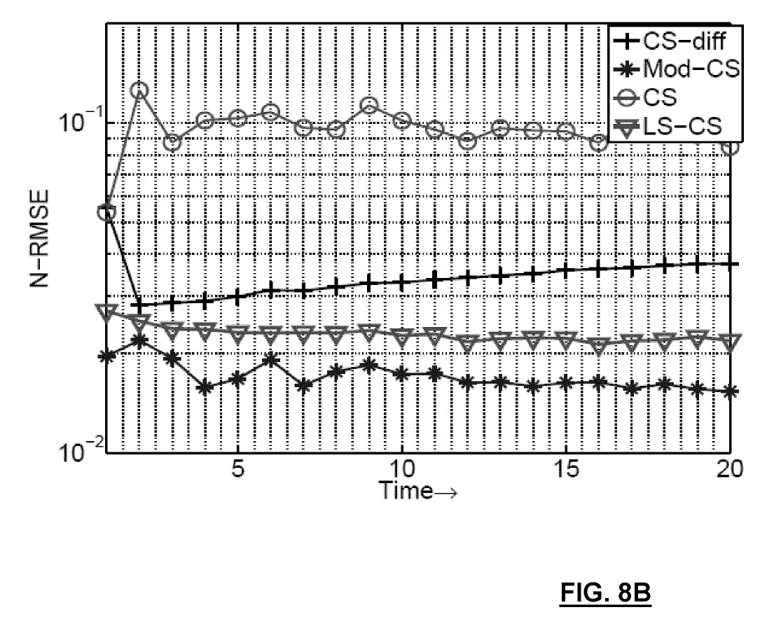

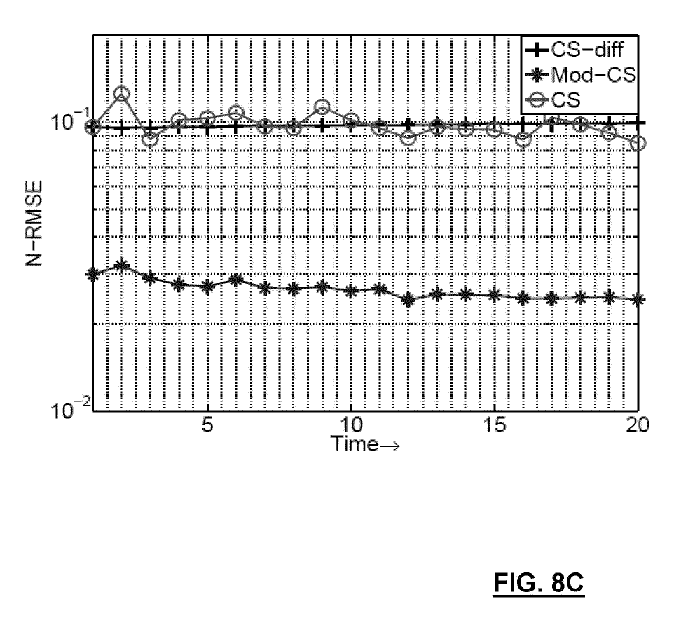

For solving the minimization problems previously described, we used CVX, http://www.standford.edu˜boyd/cvx/, for smaller sized problems (n<4096). All simulations and all results of this section and FIGS. 6A, 6B, 7A, 7B used CVX. For bigger signals/images, (i) the size of the matrix A becomes too large to store on a PC (needed by most existing solvers including the ones in CVX) and (ii) direct matrix multiplications take too much time. For bigger images and structured matrices like DFT times DWT, we wrote our own solver for by using a modification of the code in L1 Magic [25]. We show results using this code on a 256×256 larynx image sequence (n=65536) in FIGS. 8A-8C. This code used the operator form of primal-dual interior point method. With this, one only needs to store the sampling mask which takes O(n) bits of storage and one uses FFT and fast DWT to perform matrix-vector multiplications in O(n log n) time instead of O(n²) time. In fact for a b×b image the cost difference is O(b₂ log b) versus O(b⁴).

### A. Sparsified and True (Compressible) Single Image

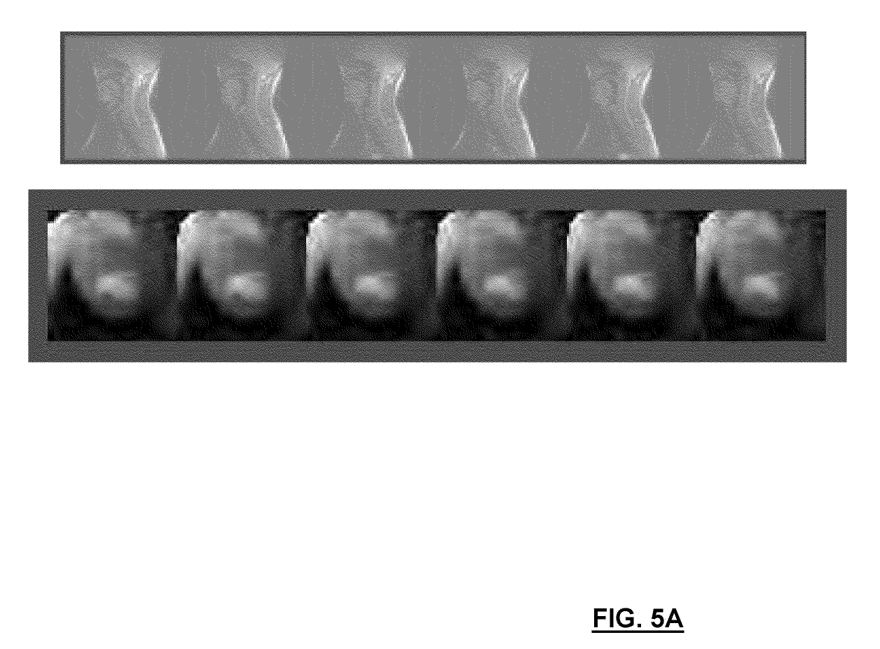

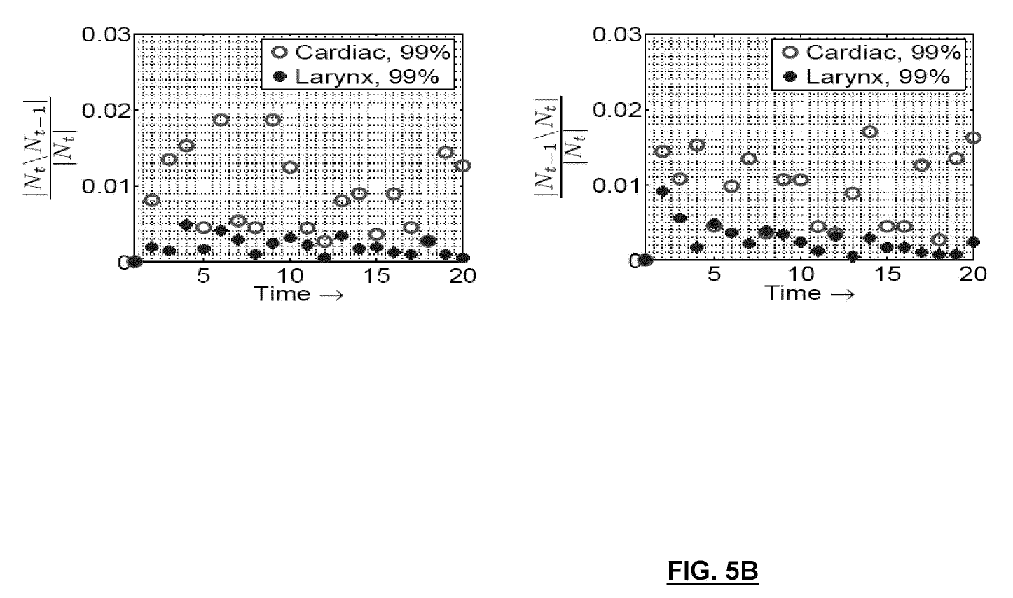

We first evaluated the single image reconstruction problem for a sparsified image. The image used was a 32×32 cardiac image shown in FIG. 5A), i.e. n=1024. Its support size s=107≈0.1n. We used the set of indices of the approximation coefficients as the known part of the support, T. Thus, k=|T|=64 and so u=|Δ|≧43 which is a significantly large fraction of s. We compare the N-RMSE in the below table.

RECONSTRUCTION ERROR (N-RMSE)

| | Sparsified | True | True |
|---|---|---|---|
| | Cardiac | Cardiac | Larynx |
| CS (H = Gᵣ, m = 0.29n) | 0.34 | 0.36 | 0.090 |
| Mod-CS (H = Gᵣ, m = 0.29n) | 0 | 0.14 | 0.033 |
| CS (H = MF, m = 0.19n) | 0.13 | 0.12 | 0.097 |
| ModCS(H = MF, m = 0.19n) | 0 | 0.11 | 0.025 |

Even with such a large unknown support size, modified-CS achieved exact reconstruction from 29% random Gaussian and 19% partial Fourier measurements. CS error in these cases was 34% and 13%, respectively.

We also did a comparison for actual cardiac and larynx images (which are only approximately sparse). The results are tabulated in the above table. Modified-CS works better than CS, though not by much since |Δ| is a large fraction of |N|. Here N refers to the b % support for any large b, e.g. b=99.

### B. Sparsified Image Sequences

We compared modified-CS with simple CS (CS at each time instance), CS-diff and LS-CS [15] for the sparsified 32×32 cardiac sequence in FIG. 3. Modified-CS was implemented as in the Algorithm previously described. At t=0, the set T was empty and we used 50% measurements. For this sequence, |Nₜ|≈0.1n=107, u=|Δ|≦10≈0.01n and e=|Δₑ|≦5≈0.005n.

Since u<<|Nₜ|, modified-CS achieves exact reconstruction with as few as 16% measurements at t>0. FIG. 6A used H=Gᵣ (compression/single-pixel imaging) and FIG. 6B used H=MF (MRI). As can be seen, simple CS has very large error. CS-diff and LS-CS also have significantly nonzero error since the exact sparsity size of both the signal difference and the signal residual is equal to/larger than the signal's sparsity size. Modified CS-error is 10⁻⁸ or less (exact for numerical implementation). Similar conclusions were also obtained for the sparsified larynx sequence.

### C. True (Compressible) Image Sequences

Finally we did the comparison for actual image sequences which are only compressible. We show results on the larynx (vocal tract) image sequence of FIG. 5A. For FIGS. 7A, 7B, we used a 32×32 block of it with random Gaussian measurements. For FIG. 8A-8C we used the entire 256×256 image sequence with partial Fourier measurements. At t=0, modified-CS, RegModCS and LS-CS used T to be the set of indices of the approximation coefficients.

For FIG. 7A, 7B, we used H=Gᵣ (random Gaussian) and m₀=0.19n. FIGS. 7A and 7B used m=0.19n,m=0.06n, respectively. At each t, RegMOdCS-MAP solved (3.3) with bₚ, σₚ² estimated from a few frames of the sequence treated as training data. The resulting γ=\hat{b}ₚ, \hat{σ}ₚ² was 0.007. RegModCS-exp-opt solved with T=\hat{N}ₜ₋₁, μ_{T}=(\hat{x}_{reg,t-1})_{T} and we experimented with many values of γ and chose the one which gave the smallest error. Notice from FIG. 7A that RegModCS-MAP gives MSEs which are very close to those of RegModCS-exp-opt.

FIGS. 8A-8C show reconstruction of the full larynx sequence using H=MF, m=0.19n and three choices of m₀. In FIG. 8A we compare the reconstructed image sequence using modified-CS with that using simple CS. The error (N-RMSE) was 8-11% for CS, while it was stable at 2% or lesser for modified-CS. Since m₀ is large enough for CS to work, the N-RMSE of CSdiff (not shown) also started at a small value of 2% for the first few frames, but kept increasing slowly over time. In FIG. 8B, 8C, we show N-RMSE comparisons with simple CS, CS-diff and LS-CS. In the plot shown, the LS-CS error is close to that of modified-CS because we implemented LS estimation using conjugate gradient and did not allow the solution to converge (forcibly ran it with a reduced number of iterations). Without this tweeking, LS-CS error was much higher, since the computed initial LS estimate itself was inaccurate.

Notice from both FIGS. 7A, 7B and FIG. 8A-C, that modifiedCS and RegModCS significantly outperform CS and CS-diff. In most cases, both also outperform LS-CS. RegModCS always outperforms all the others, with the difference being largest when m is smallest, i.e. in FIG. 7B. Here the advantage of RegModCS over modified-CS is really seen. In FIGS. 7A, 7B, and 8C, CS-diff performs so poorly primarily because the initial error at t=0 is very large (since we use only m₀=0.19n). As a result the difference signal at t=1 is not compressible enough, making its error large and so on. But even when m0 is larger and the initial error is small, CS-diff is still the worst, although the difference in errors is not as large, e.g. in FIG. 8B.

### 3.2 Conclusions

We studied the problem of reconstructing a sparse signal from a limited number of its linear projections when the support is partly known (although the known part may contain some errors). Denote the known support by T Modified-CS solves an l₁ relaxation of the following problem: find the signal that is sparsest outside of T and that satisfies the data constraint. We derived sufficient conditions for exact reconstruction using modified-CS. These are much weaker than those for CS when the sizes of the unknown part of the support and of errors in the known part are small compared to the support size. An important extension, called RegModCS, was developed that also uses prior signal estimate knowledge. Simulation results showing greatly improved performance of modified-CS and RegModCS using both random Gaussian and partial Fourier measurements are shown on both sparse and compressible signals and image sequences.

The most compelling application of our work is for recursive reconstruction of time sequences of sparse/compressible signals, e.g. for real-time dynamic MRI applications. Many MRI applications of CS minimize the total variation (TV) norm. The modified-CS idea can be applied easily for the TV norm as follows. Let T contain the set of pixel indices whose spatial gradient magnitude was nonzero at the previous time (or should be nonzero based on some other available prior knowledge). Minimize the TV norm of the image along all pixels not in T subject to the data constraint. Also, by designing homotopy methods for ModCS or RegModCS, one can efficiently handle sequentially arriving measurements and this can be very useful for MRI applications.

Thus, we have developed extensions to modified-CS. One important extension, called RegModCS, was developed that also uses prior signal estimate knowledge. Simulation results show greatly improved performance of modified-CS and RegModCS using both random Gaussian and partial Fourier measurements on both sparse and compressible signals and image sequences.

### 4. Least Squares CS-Residual (LS-CS): Compressive Sensing on Least Squares Residual

We consider the problem of recursively and causally reconstructing time sequences of sparse signals (with unknown and time-varying sparsity patterns) from a limited number of noisy linear measurements. The sparsity pattern is assumed to change slowly with time. The idea of our proposed solution, LS-CS-residual (LS-CS), is to replace compressed sensing (CS) on the observation by CS on the least squares (LS) residual computed using the previous estimate of the support. The key idea of this solution, LS-CS-residual (LS-CS) is to replace CS on the observation by CS on the least squares (LS) residual computed using the previous support estimate. Its complexity is equal to that of simple CS which is O(Nm³) where m is the signal length and N is the time duration [19, Table I].

Here, we do “CS”, whether in simple CS or in CS-residual, using the Dantzig selector (DS) [20]. This choice was motivated by the fact that its guarantees are stronger and its results are simpler to apply/modify (they depend only on signal support size) as compared to those for BPDN given in [7] (these depend on the actual support elements). We have also used BPDN for practical experiments with larger sized images since it runs faster. Between DS and Lasso (l₂ constrained l₁ minimization) [13],[21], either can be used.

Given observation, y, the Dantzig selector [20] solves

$${min}_{ζ} {‖ ( ζ ) ‖}_{1} s . t . {‖ {A}^{′} ( y - A ζ ) ‖}_{∞} < λ \qquad ( 4.1 )$$

Now consider the recursive reconstruction problem. If the support of xₜ, Nₜ, were known at each t, we could simply compute its least squares (LS) estimate along Nₜ while setting all other values to zero. We refer to this estimate as the “genie-aided” LS estimate. When Nₜ is not known, one could do simple CS at each time, i.e. solve (4.1) with y=yₜ, followed by thresholding the output to estimate its support, and then do the same thing using the support estimate \hat{N}ₜ instead of Nₜ. But in doing so, we are throwing away the information contained in past observations. If the available number of measurements, n, is small, this incurs large error.

To use the information contained in past observations, along with the knowledge that support changes slowly, we propose the following idea. Assume for a moment that the support has not changed from t−1 to t. Use T :=\hat{N}ₜ₋₁ to compute an initial LS estimate and compute the LS residual, i.e. compute

(\hat{x}_{t,init})_{T}=A_{T}^{†}yₜ, (\hat{x}_{t,init})_{T}_{^{C}}=0

\tilde{y}_{t,res}=yₜ−A\hat{x}_{t,init}

Notice that the LS residual, \tilde{y}_{t,res}, can be rewritten as

\tilde{y}_{t,res}=Aβₜ+wₜ, βₜ:=xₜ−\hat{x}_{t,init} (4.2)

where βₜ is a |T∪Δ|-sparse vector with (βₜ)_{(T∪Δ)}_{^{c}}=0,

(βₜ)_{T}=(xₜ)_{T}−A_{T}^{†}yₜ=−A_{T}^{†}(wₜ+A_{Δ}(xₜ)_{Δ}),

(βₜ)_{Δ}=(xₜ)_{Δ}−0=(xₜ)_{Δ} (4.3)

The above follows because A_{T}^{†}A_{T}=I and yₜ=Axₜ+wₜ=A_{N}(xₜ)_{N}+wₜ=A_{N∩T}(xₜ)_{N∩T}+A_{N∩T}_{^{c}}(xₜ)_{N∩T}_{^{c}}+wₜ=A_{T}(xₜ)_{T}+A_{Δ}(xₜ)_{Δ}+wₜ. Here N=Nₜ. The last equality holds because Δ=N∩T^{c} and N∩T [symbol] T.

Notice that Δ [symbol] (Nₜ\Nₜ₋₁)∪(Nₜ₋₁\T) and Δ_{c} [symbol] (Nₜ₋₁\Nₜ)∪(T\Nₜ₋₁). Here, |Nₜ\Nₜ₋₁|≦Sₐ and |Nₜ₋₁\Nₜ|≦S_{α}. If |Δ| and |Δₑ| are small enough (i.e. if S_{α} is small enough and T is an accurate enough estimate of Nₜ₋₁) and A is incoherent enough to ensure that ∥A_{T}′A_{Δ}∥ is small enough, βₜ will be small (compressible) along T. In other words, βₜ will be only |Δ|-approximately-sparse. In this case, doing CS on \tilde{y}_{t,res} should incur much less error than doing CS on yₜ (simple CS), which needs to reconstruct a |Nₜ|-sparse signal, xₜ. This is the key idea of our approach.

We do CS on the LS residual (CS-residual), i.e. we solve (4.1) with y=\tilde{y}_{t,res} and denote its output by \hat{β}ₜ. Now,

\hat{x}_{t,CSres}:=\hat{β}ₜ+\hat{x}_{t,init} (4.4)

can serve as one possible estimate of xₜ. But, as explained in [20], since \hat{β}ₜ is obtained after l₁ norm minimization, it will be biased towards zero. Thus, \hat{x}_{t,CSres} will also be biased. We can use the Gauss-Dantzig selector trick of [20] to reduce the bias. To do that, we first detect the new additions as follows:

\hat{N}_{t,det}=T∪{iε[1,m]:|(\hat{x}_{t,CSres})ᵢ|>α} (4.5)

and then we use \tilde{T}_{det:=\hat{N}}_{t,det} to compute an LS estimate

(\hat{x}_{t,det})_{\tilde{T}}_{det}=A_{\tilde{T}det}^{†}yₜ,(\hat{x}_{t,det})_{(\tilde{T}det)}_{^{c}}=0 (4.6)

If \tilde{T}_{det}=Nₜ,\hat{x}_{t,det} will be unbiased. In fact, if will be the best linear unbiased estimate, in terms of minimizing the mean squared error (MSE). But even if \tilde{T}_{det} is roughly accurate, the bias and MSE will be significantly reduced.

If the addition threshold, α, is not large enough, occasionally there will be some false detections (coefficients whose true value is zero but they wrongly get detected due to error in the CS-residual step). Also, there may have been actual removals from the true support. This necessitates a “deletion” step to delete these elements from the support estimate. If this is not done, the estimated support size could keep increasing over time, causing A_{T}′ A_{T} to become more and more ill-conditioned and the initial LS estimates to become more and more inaccurate.

A simple approach to do deletion is to apply thresholding to \hat{x}_{t,det}, i.e. to compute

\hat{N}ₜ=\tilde{T}_{det}\{iε\tilde{T}_{det}:|(\tilde{x}_{t,det})ᵢ|≦α_{det}} (4.7)

The above is better than deleting using \hat{x}_{t,CSres} which, as explained above, usually has a larger MSE.

A final LS estimate can be computing using \tilde{T}:=\hat{N}ₜ.

(\hat{x}ₜ)_{\tilde{T}}=A_{\tilde{T}}^{†}yₜ,(\hat{x}ₜ)_{\tilde{T}}_{^{c}}=0 (4.8)

In most places herein, we use “addition” (“removal”) to refer to additions (removals) from the actual support, while using “detection” (“deletion”) to refer to additions (removals) from the support estimate. Occasionally, this is not followed.

### A. LS CS-Residual (LS-CS) Algorithm

We give the LS CS-residual (LS-CS) algorithm below. Initialization (t=0): At the initial time, t=0, we run simple CS with a large enough number of measurements, n₀>n (usually much larger), i.e. we solve (4.1) with y=y₀ and A=A₀=H₀Φ (H₀, and hence A₀, will be an n₀×m matrix). This is followed by support estimation and then LS estimation as in the Gauss-Dantzig selector [7]. We denote the final output by \hat{x}₀ and its estimated support by \hat{N}₀. For t>0 do,
1) Initial LS. Use T :=\hat{N}ₜ₋₁ to compute the initial LS estimate \hat{x}_{t,init}, and the LS residual, \tilde{y}_{t,res}, using (4.2).
2) CS-residual. Do CS (Dantzig selector) on the LS residual, i.e. solve (4.1) with y=\tilde{y}_{t,res} and denote its output by \hat{β}ₜ. Compute \hat{x}_{t,CSres} using (4.4).
3) Detection and LS. Use (4.5) to detect additions to the support to get \tilde{T}_{det} :=\hat{N}_{t,det}. Compute the LS estimate, \hat{x}_{t,det}, using \tilde{T}_{det}, as given in (4.6).
4) Deletion and LS. Use (4.7) to detect deletions from the support to get \tilde{T} :=\hat{N}ₜ. Compute the LS estimate, \hat{x}ₜ, using \tilde{T}, as given in (4.8).
5) Output \hat{x}ₜ and \hat{z}ₜ=Φ\hat{x}ₜ. Feedback \hat{N}ₜ. Increment t and go to step 1.

### B. Threshold Setting Heuristics

If n is large enough (to ensure that A_{N}_{ₜ} is well-conditioned), a thumb rule from literature is to set α at roughly the noise level [7]. If the SNR is high enough, we recommend setting α_{del} to a larger value (since in that case, \hat{x}_{det} will have much smaller error than \hat{x}_{CSres}), while in other cases, α_{del}=α is better. Higher α_{del} ensures quicker deletion of extras.

When n is not large enough, instead of setting an explicit threshold α, one should keep adding the largest magnitude elements of \hat{x}_{det} until A_{\tilde{T}det} exceeds a condition number threshold, α_{del} can be set to a fraction of the minimum nonzero coefficient value (if known). Also, α_{del} should again be larger than the implicit α being used.

Another heuristic, which ensures robustness to occasional large noise, is to limit the maximum number of detections at a given time to a little more than Sₐ (if Sₐ is known).

### C. Kalman Filtered CS-Residual (KF-CS)

Now, LS-CS does not use the values of (\hat{x}t-1)_{T} to improve the current estimate. But often, in practice, coefficient values also change slowly. To use this information, we can replace the initial LS estimate by a regularized LS estimate. If training data is available to learn a linear prior model for signal coefficients' change, this can be done by using a Kalman filter (KF). We develop and study the KF-CS algorithm in [21],[22]. As we demonstrate in [22], KF-CS significantly improves upon LS-CS when n is small and so A_{T} can occasionally become ill-conditioned (this results in LS-CS instability, but does not affect KF-CS much, as long as this occurs only occasionally).

Thus, in this section we have formulated the problem of recursive reconstruction of sparse signal sequences from noisy observations as one of noisy CS with partly known support (the support estimate from the previous time serves as the “known” part). Our proposed solution, LS CS-residual replaces CS on the raw observation by CS on the LS residual, computed using the known part of the support.

4.2 Dynamic MRI reconstruction example

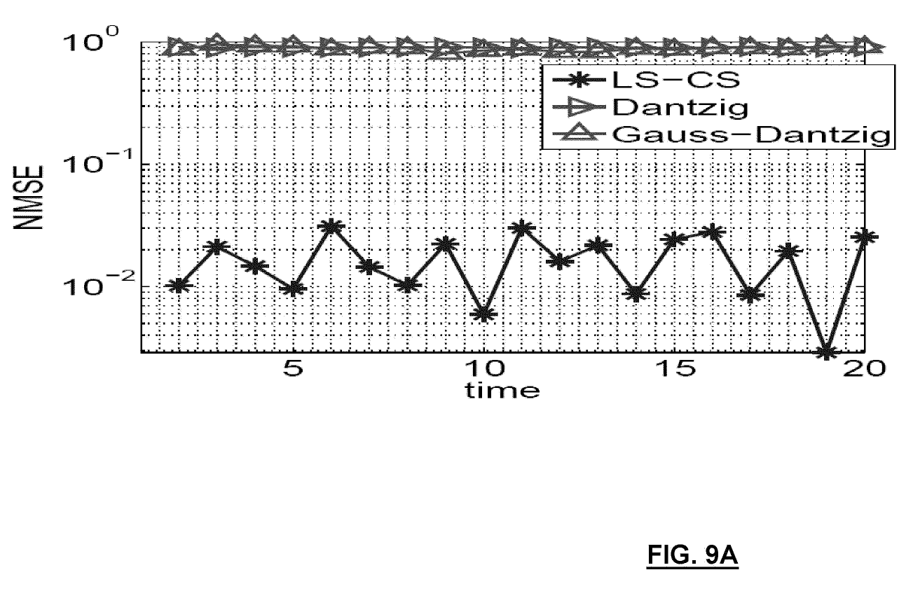

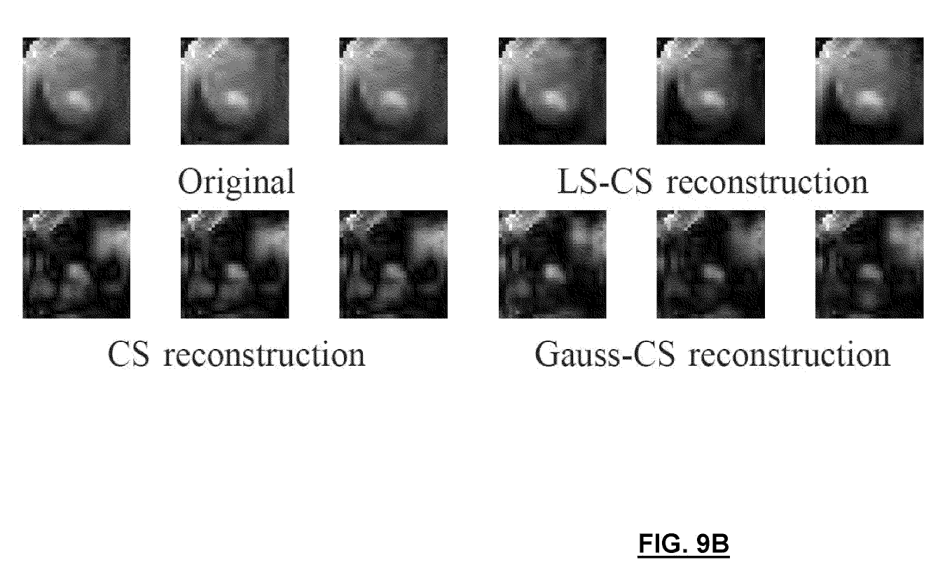

In FIG. 9A-9B, we show the applicability of LS-CS to accurately reconstruct a sparsified cardiac image sequence from only 35% (simulated) MRI measurements. For FIG. 9A-9B, the sparsity basis was the two-level Daubechies-4 2D DWT. Images were 32×32 (m=1024) and were sparsified by retaining the largest magnitude DWT coefficients that make up 99.5% of the total image energy and computing the inverse DWT. The support size of the sparsified DWT vector varied between 106-110, and the number of additions to (or removals from) the support from any t−1 to t varied between 1-3. Denote the 1D DWT matrix by W and the DFT matrix by F. Then Φ=W [symbol] W and the measurement matrix, H=Mᵣₛ(F [symbol] F)/32 where Mᵣₛ is an n×m random row selection matrix and [symbol] denotes the Kronecker product. We used n=0.35m and n₀=0.8m. Noise was zero mean i.i.d. Gaussian with variance σ²=0.125. Both LS-CS and CS used λ=1.5σ.

### 4.3. Conclusions

We formulated the problem of recursive reconstruction of sparse signal sequences from noisy observations as one of noisy CS with partly known support (the support estimate from the previous time serves as the “known” part). Our proposed solution, LS CS-residual (LS-CS), replaces CS on the raw observation by CS on the LS residual, computed using the known part of the support. We obtained bounds on CS-residual error. When the number of available measurements, n, is small, we showed that our bound is much smaller than the CS error bound if |Δ|, |Δₑ| are small enough. We used this bound to show the stability of LS-CS over time. By “stability” we mean that |Δ|, |Δₑ| remain bounded by time-invariant values. Extensive simulation results backing our claims are shown.

### 5. APPLICATIONS

The present invention includes use of recursive algorithms for causally reconstructing a time sequence of (approximately) sparse signals from a greatly reduced number of linear projection measurements. By “recursive”, we mean use only the previous estimate and the current measurements to get the current estimate. The signals are sparse in some transform domain referred to as the sparsity basis and their sparsity patterns (support set of the sparsity basis coefficients) can change with time. One important example of the above problem occurs in dynamic magnetic resonance imaging (MRI) for real-time medical applications such as interventional radiology, MR image guided surgery, or functional MRI to track brain activation changes. MRI is a technique for cross-sectional imaging that sequentially captures the 2D Fourier projections of the cross-section to be reconstructed. Cross-sectional images of the brain, heart, larynx or other human organ images are usually piecewise smooth, and thus approximately sparse in the wavelet domain.

In a time sequence, the sparsity pattern changes with time, but slowly. Slow sparsity pattern change has been empirically verified for medical image sequences and for video. Since MR data acquisition is sequential, the ability to accurately reconstruct with fewer measurements directly translates to reduced scan times. Shorter scan times along with online (causal) and fast (recursive) reconstruction allow the possibility of real-time imaging of fast changing physiological phenomena.

The present invention provides for addressing the problem of casually and recursively reconstructing sparse signal sequences using fewer measurements than those needed for simple CS. The computational complexity of the algorithms is only as much as that of simple CS.

It should be further understood that the present invention provides numerous advantages. One such advantage is that a method can use a current observation, the support estimate from a previous time instant, and the previous observations to obtain an initial estimate of the current signal. The estimate is then refined using compressed sensing. Thus, the estimate is more accurate than alternative approaches without such an estimate.

Another advantage of the present invention is that there is a theoretical guarantee on performance, which is absent from other methods. Thus, the method can be applied to any problem that satisfies a given set of assumptions. In short, the present invention makes real-time reconstruction of a time-sequence of sparse signals/images from incoherent measurements possible.

The present invention may be applied to a number of applications where CS is used or may be used. A first example of an application in which the present invention may be applied is in real-time dynamic MR image reconstruction. One advantage of real-time dynamic MR image reconstruction is the ability to provide interventional radiology.

Another application of the present invention is to improve a single-pixel video camera. The methodology of the present invention enables a real-time display for images obtained using a single-pixel video camera. Of course, the present invention may be used in any number of contexts involving sparse signals, including in sensor networks.

Another application of the present invention is to modify greedy algorithms for sparse reconstruction to use them for recursively reconstructing sparse signal sequences.

Thus, applications of the present invention may include, without limitation, real-time dynamic MRI for interventional radiology or image guided surgery, functional MRI, real-time single-pixel video imaging, video compression, radar image sequence reconstruction, or any number of other applications.

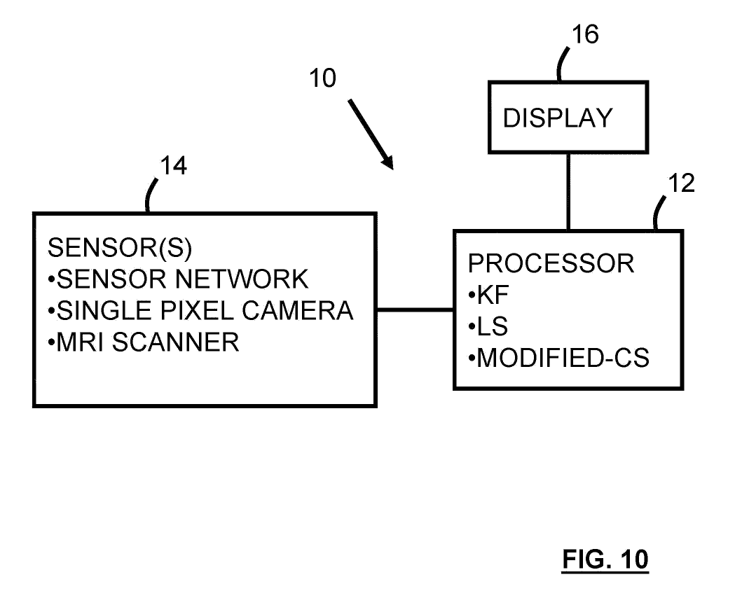

FIG. 10 is a block diagram illustrating an apparatus 10 of the present invention. The apparatus 10 includes a processor 12 which may be a digital processor. The processor 12 is programmed or otherwise configured to perform one or more of the methods previously discussed, such as least squares compressed sensing, Kalman filtered compressed sensing, or modified compressed sensing. For example the processor 12 may be configured to perform compressed sensing on the sparse signal sequence in a manner which casually estimates a time sequence of spatially sparse signals and generates a real-time reconstructed signal. Alternatively, the processor 12 may be configured to work with static signals. As shown in FIG. 10, a display 16 is operatively connected to the processor 12. The apparatus may be configured to display a visual representation of a signal (or image) on the display 16. In addition, one or more sensors 14 are operatively connected to the processor 12. Examples of sensors which may be connected include sensors from a sensor network, a single pixel camera, or an MRI scanner or other type of scanner.

### 6. OTHER VARIATIONS, OPTIONS, AND ALTERNATIVES

The present invention further contemplates other options, variations, and alternatives in the design and/or analysis of recursive algorithms for causally reconstructing a time sequence of sparse signals and the use of such algorithms in any number of applications. The present invention is not to be limited to or by the specific examples provided herein or the specific algorithms provided.

### 7. REFERENCES

Each of the references set forth below is hereby incorporated by reference in its entirety.
[1] E. Candes, J. Romberg, and T. Tao, “Robust uncertainty principles: Exact signal reconstruction from highly incomplete frequency information,” IEEE Trans. Info. Th., vol. 52(2), pp. 489-509, February 2006.
[2] A. J. Martin, O. M. Weber, D. Saloner, R. Higashida, M. Wilson, M. Saeed, and C. B. Higgins, “Application of MR Technology to Endovascular Interventions in an XMR Suite,” Medial Mundi, vol. 46, December 2002.
[3] M. Lustig, D. Donoho, and J. M. Pauly, “Sparse mri: The application of compressed sensing for rapid mr imaging,” Magnetic Resonance in Medicine, vol. 58(6), pp. 1182-1195, December 2007.
[4] J. Shi and C. Tomasi, “Good features to track,” in IEEE Conf. on Comp. Vis. Pat. Rec. (CVPR), 1994, pp. 593-600.
[5] M. Wakin, J. Laska, M. Duarte, D. Baron, S. Sarvotham, D. Takhar, K. Kelly, and R. Baraniuk, “An architecture for compressive imaging,” in IEEE Intl. Conf. Image Proc., 2006.
[6] D. Donoho, “Compressed sensing,” IEEE Trans. on Information Theory, vol. 52(4), pp. 1289-1306, April 2006.
[7] E. Candes and T. Tao, “The dantzig selector: statistical estimation whenp is much larger than n,” Annals of StatistiCS, 2006.
[8] U. Gamper, P. Boesiger, and S. Kozerke, “Compressed sensing in dynamic mri,” Magnetic Resonance in Medicine, vol. 59(2), pp. 365-373, January 2008.
[9] T. Kailath, A.H. Sayed, and B. Hassibi, Linear Estimation, Prentice Hall, 2000.
[10] J. Garcia-Frias and I. Esnaola, “Exploiting prior knowledge in the recovery of signals from noisy random projections,” in Data Compression Conference, 2007.
[11] K. Egiazarian, A. Foi, and V. Katkovnik, “Compressed sensing image reconstruction via recursive spatially adaptive filtering,” in IEEE Intl. Conf. Image Proc., 2007.
[12] S. Ji, Y. Xue, and L. Carin, “Bayesian compressive sensing,” IEEE Trans. Sig. Proc., to appear.
[13] N. Vaswani, “Analyzing least squares and kalman filtered compressed sensing,” in IEEE Intl. Conf. Acoustics, Speech, Sig. Proc. (ICASSP), 2009.
[14] E. Candes and T. Tao, “Decoding by linear programming,” IEEE Trans. Info. Th., Vol. 51(12), pp. 4203-4215, December 2005.
[15] C. Qiu, W. Lu, and N. Vaswani, “Real-time dynamic mri reconstruction using kalman filtered cs,” in IEEE Intl. Conf. Acoustics, Speech, Sig. Proc. (ICASSP), 2009.
[16] J. Haupt and R. Novak, “Signed reconstruction from noisy random projections,” IEEE Trans. Info. Th., September 2006.
[17] C. Rozell, D. Johnson, R. Baraniuk, and B. Olshausen, “Locally competitive algorithms for sparse approximation,” in IEEE Intl. Conf. Image Proc. (ICIP), 2007.
[18]H. Jung, K. H. Sung, K. S. Nayhak, E. Y. Kim, and J. C. Ye, “k-t focus: a general compressed sensing framework for high resolution dynamic mri”, Magnetic Resonance in Medicine, Vol. 61, pp. 103-116, 2009.
[19] A. Khajehnejad, W. Xu, A. Avestimehr, and B. Hassibi, “Weighed 11 minimization of sparse recovery with prior information,” in IEEE Intl. Symp. Info. Theory (ISIT), 2009.
[20] S. Chen., D. Donoho, and M. Saunders, “Atomic decomposition by basis pursuit,” SIAM Journal of Scientific Computation, vol. 20, pp. 33-61, 1998.
[21] N. Vaswani, “Kalman Filtered Compressed sensing,” in IEEE Intl. Conf. Image Proc. (ICIP), 2008.
[22] N. Vaswani, “Kf-cs: Compressive sensing on kalman filtering residual,” Arxiv preprint arXiv: 0912. 1628, 2009.
[23]H. V. Poor, An Introduction to Signal Detection and Estimation, 2^{nd} ed. Springer.
[24] V. Cevher, A. Sankaranarayanan, M. Duarte, D. Reddy, R. Baraniuk, and R. Chellappa, “Compressive sensing for background subtraction,” in Eur. Conf. on Comp. Vis. (ECCV), 2008.
[25] E. Candes and J. Romberg, “L1 Magic Users Guide,” October 2005.

What is claimed is:

1. A method for real-time reconstruction, the method comprising:
receiving a sparse signal sequence one at a time; and
performing compressed sensing on the sparse signal sequence in a manner which casually estimates a time sequence of spatially sparse signals and generates a real-time reconstructed signal.

2. The method of claim 1 wherein the compressed sensing is Kalman filtered compressed sensing.

3. The method of claim 1 wherein the compressed sensing is least squares compressed sensing.

4. The method of claim 1 wherein the compressed sensing is modified-compressed sensing.

5. The method of claim 1 further comprising displaying a visual representation of the real-time reconstructed signal on a display.

6. The method of claim 5 wherein the visual representation comprises a series of magnetic resonance images.

7. The method of claim 5 wherein the visual representation comprises a series of computed tomography images.

8. The method of claim 1 wherein the sequence of sparse signals is generated by a single pixel camera.

9. The method of claim 1 wherein the sequence of sparse signals is generated by one or more sensors in a sensor network.

10. The method of claim 1 wherein the step of performing the compressed sensing comprises using compressed sensing to estimate signal support at an initial time instant, running a Kalman Filter for a reduced order model until innovation or filtering error increases, and if innovation or filtering error increases then running compressed sensing on the filtering error.

11. The method of claim 1 wherein at each time the step of performing the compressed sensing comprises computing a Least Squares initial estimate and the Least Squares residual.

12. The method of claim 1 wherein the step of performing compressed sensing on the sparse signal sequence comprises performing a reconstruction of a signal from the sparse signal sequence by solving a problem both satisfying a data constraint and having a support set containing a smallest number of new additions to a partially known support set.

13. The method of claim 12 wherein the partially known support set is based on a support set of a prior sparse signal within the sparse signal sequence.

14. An apparatus for providing real-time reconstruction of a time-sequence of sparse signals, the apparatus comprising:
at least one sensor for sensing a sparse signal sequence;
a processor configured to perform compressed sensing on the sparse signal sequence in a manner which casually estimates a time sequence of spatially sparse signals and generates a real-time reconstructed signal.

15. The apparatus of claim 14 wherein the sensor is a sensor of a single pixel camera.

16. The apparatus of claim 14 wherein the sensor is a sensor within a sensor network.

17. The apparatus of claim 14 wherein the sensor is a magnet resonance image scanner

18. The apparatus of claim 14 wherein the processor is a digital processor.

19. A method for performing Kalman filtered compressed sensing, comprising:
receiving a sparse signal sequence one at a time;
estimating a support set using compressed sensing for a first sparse signal within the sparse signal sequence;
applying a reduced order Kalman filter with the support set to subsequent sparse signals within the sparse signal sequence;
estimating additions to the support set using compressed sensing and updating the support set.

20. The method of claim 19 wherein the estimating additions to the support set comprises applying compressed sensing to Kalman innovations.

21. The method of claim 19 wherein the estimating additions to the support set comprises applying compressed sensing to filtering error.

22. The method of claim 19 further comprising displaying a visual representation of sparse signals within the sparse signal sequence on a display.

23. A method for performing least squares compressed sensing, comprising:
receiving a sparse signal sequence one at a time;
estimating a support set using compressed sensing for a first sparse signal within the sparse signal sequence;
applying least squares estimation with the support set to subsequent sparse signals within the sparse signal sequence;
estimating additions to the support set using compressed sensing and updating the support set.

24. The method of claim 23 further comprising displaying a visual representation of sparse signals within the sparse signal sequence on a display.

25. A method for performing modified compressed sensing, comprising:
receiving a sparse signal;
determining a partially known support set, T;
performing a reconstruction of a signal from the sparse signal by solving a problem both satisfying a data constraint and having a support set containing a smallest number of new additions to the partially known support set, T.

26. The method of claim 25 further comprising outputting the signal.

27. The method of claim 25 further comprising displaying a visual representation of the signal.

28. The method of claim 25 wherein the signal comprises image data.

29. The method of claim 25 wherein the signal being a representation of magnetic resonance imaging data.

30. The method of claim 25 wherein the determining the partially known support set, T, is performed by using a support set of a prior sparse signal in a time sequence of sparse signals.
